(19) United States
(12) Patent Application Publication
(10) Pub. No.: US 2025/0040334 A1
(43) Pub. Date: Jan. 30, 2025

(54) PHOTOELECTRIC DEVICE MODULE AND MANUFACTURING METHOD THEREOF

(71) Applicant: Raynergy Tek Incorporation, HSINCHU (TW)

(72) Inventors: Yi-Ming CHANG, HSINCHU (TW); Cheng-En TSAI, HSINCHU (TW); Chung-Wei HSU, HSINCHU (TW)

(21) Appl. No.: 18/784,889

(22) Filed: Jul. 25, 2024

Related U.S. Application Data
(60) Provisional application No. 63/515,592, filed on Jul. 26, 2023.

(30) Foreign Application Priority Data
May 22, 2024 (TW) 113118941

(51) Int. Cl. H10K 39/32; H10K 39/38; H10K 71/50

(52) U.S. Cl. CPC H10K 39/32; H10K 39/38; H10K 71/50

(57) ABSTRACT

The present disclosure provides a photoelectric device module and a manufacturing method thereof. The photoelectric device module includes a circuit module and a photoelectric conversion module. The circuit module includes a first electrode. The photoelectric conversion module is disposed on the circuit module, in which the photoelectric conversion module includes a second electrode, a photoactive layer, a light-transmitting electrode, and a light-transmitting substrate. The second electrode is electrically connected to the first electrode. The photoactive layer is disposed on the second electrode. The light-transmitting electrode is disposed on the photoactive layer. The light-transmitting substrate is disposed on the light-transmitting electrode.

### CROSS-REFERENCE TO RELATED APPLICATION

This application claims priority to U.S. Provisional Application Ser. No. 63/515,592 filed Jul. 26, 2023, and Taiwan Application Serial Number 113118941, filed May 22, 2024, the disclosures of which are incorporated herein by reference in their entireties.

### BACKGROUND

### Field of Invention

The present disclosure relates to a photoelectric device module and a manufacturing method thereof.

### Description of Related Art

Matrix photoelectric device modules have various applications. For example, active-matrix organic light-emitting diode (AMOLED) is the current mainstream display technology, and it is mainly composed of light-emitting devices and drive circuits. Similar applications can also be used for sensor applications, such as changing the drive circuits into readout circuit (ROIC) and then combining the ROIC and photodiodes to form an image sensor, such as a CMOS image sensor, a fingerprint scanner, or a digital X-ray imaging device.

In order to improve the performance of photodiodes (such as photoelectric conversion efficiency, sensitivity, emission wavelength range and/or photosensitive wavelength range) and reduce the cost of photodiodes, many new materials that can be applied to photodiodes have been developed. However, these materials may not be directly applicable to current silicon-based image sensor manufacturing. For example, the high temperatures of the process or physical impact during vacuum coating may damage the properties of these materials.

### SUMMARY

The present disclosure provides a photoelectric device module including a circuit module and a photoelectric conversion module. The circuit module includes a first electrode. The photoelectric conversion module is disposed on the circuit module, in which the photoelectric conversion module includes a second electrode, a photoactive layer, a light-transmitting electrode, and a light-transmitting substrate. The second electrode is electrically connected to the first electrode. The photoactive layer is disposed on the second electrode. The light-transmitting electrode is disposed on the photoactive layer. The light-transmitting substrate is disposed on the light-transmitting electrode.

In some embodiments, the first electrode is in direct contact with the second electrode.

In some embodiments, the first electrode and the second electrode form an Ohmic junction.

In some embodiments, the light-transmitting substrate allows visible light, near-infrared light, or short-wave infrared (SWIR) light to pass through.

In some embodiments, a material of the light-transmitting substrate includes polyimide (PI), polyethylene terephthalate (PET), polyethylene naphthalate (PEN), polycarbonate (PC), silicon (Si), or combinations thereof.

In some embodiments, the photoelectric device module further includes an optical functional layer, in which the optical functional layer is disposed on the light-transmitting substrate or between the light-transmitting electrode and the light-transmitting substrate.

In some embodiments, the photoelectric device module further includes a conductive block, in which the first electrode is electrically connected to the second electrode through the conductive block.

In some embodiments, the photoelectric device module further includes a first carrier transport layer disposed between the light-transmitting electrode and the photoactive layer and a second carrier transport layer disposed between the photoactive layer and the second electrode.

In some embodiments, the second electrode covers a lower surface and a side surface of the second carrier transport layer, a side surface of the photoactive layer, and a side surface of the first carrier transport layer.

In some embodiments, the circuit module further includes a third electrode, and the third electrode is electrically connected to the light-transmitting electrode through a conductive block.

In some embodiments, the photoelectric device module further includes a sealant, in which the sealant is disposed between an edge of the photoelectric conversion module and an edge of the circuit module, and the sealant, the photoelectric conversion module, and the circuit module surround a closed chamber.

In some embodiments, the photoactive layer includes an organic semiconductor, an inorganic semiconductor, a quantum dot, perovskite, or combinations thereof.

The present disclosure provides a method of manufacturing a photoelectric device module, and it includes the following operations. A circuit module is received, in which the circuit module includes a first electrode. A photoelectric conversion module is formed, which includes: forming a light-transmitting electrode on a light-transmitting substrate, forming a photoactive layer on the light-transmitting electrode, and forming a second electrode on the photoactive layer. The circuit module and the photoelectric conversion module are connected so that the second electrode is electrically connected to the first electrode.

In some embodiments, connecting the circuit module and the photoelectric conversion module is performed by bonding, adhering, or welding.

In some embodiments, the method further includes: before forming the light-transmitting electrode on the light-transmitting substrate, forming an optical functional layer to cover an upper surface of the light-transmitting substrate.

In some embodiments, the method further includes: before or after forming the light-transmitting electrode on the light-transmitting substrate, forming an optical functional layer to cover a lower surface of the light-transmitting substrate.

In some embodiments, the method further includes: disposing a sealant between an edge of the photoelectric conversion module and an edge of the circuit module to form a closed chamber surrounded by the sealant, the photoelectric conversion module, and the circuit module.

In some embodiments, the method further includes: before forming the photoactive layer on the light-transmitting electrode, forming a first carrier transport layer on the light-transmitting electrode; and before forming the second electrode on the photoactive layer, forming a second carrier transport layer on the photoactive layer.

### BRIEF DESCRIPTION OF THE DRAWINGS

The present disclosure can be more fully understood by reading the following detailed description of the embodiments and referring to the accompanying drawings.

FIG. 1 is a flowchart of a method of manufacturing a photoelectric device module according to various embodiments of the present disclosure.

FIGS. 2A to 2D are schematic cross-sectional views of intermediate stages of manufacturing a photoelectric device module according to various embodiments of the present disclosure.

FIGS. 3A to 3B are schematic cross-sectional views of intermediate stages of manufacturing a photoelectric device module according to various embodiments of the present disclosure.

FIGS. 4A to 4B are schematic cross-sectional views of intermediate stages of manufacturing a photoelectric device module according to various embodiments of the present disclosure.

FIG. 5A is a schematic cross-sectional view of a photoelectric device module according to various embodiments of the present disclosure.

FIG. 5B is a schematic cross-sectional view of forming the photoelectric conversion module of FIG. 5A.

FIG. 6 is a schematic cross-sectional view of a photoelectric device module of Example 1.

FIG. 7 is a schematic cross-sectional view of a photoelectric conversion module of Comparative Example 1.

FIG. 8 is a schematic cross-sectional view of a photoelectric device module of Comparative Example 2.

FIG. 9 is a current density-voltage diagram.

FIG. 10 is an external quantum efficiency-wavelength diagram.

FIG. 11 is a detectivity-wavelength diagram.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The present disclosure provides a photoelectric device module and a method of manufacturing the same. In the method of manufacturing the photoelectric device module, a photoelectric conversion module is first manufactured, and then the photoelectric conversion module and a circuit module are connected to form the photoelectric device module. Compared with a process of directly depositing multiple films of a photoelectric conversion module on a circuit module, the manufacturing method of the present disclosure can prevent the process of forming the photoelectric device module (such as the deposition process) from affecting the material properties in the photoelectric conversion module. Therefore, the photoelectric device module of the present disclosure can have excellent photoelectric properties, such as high current density, high external quantum efficiency (EQE), and high detectivity.

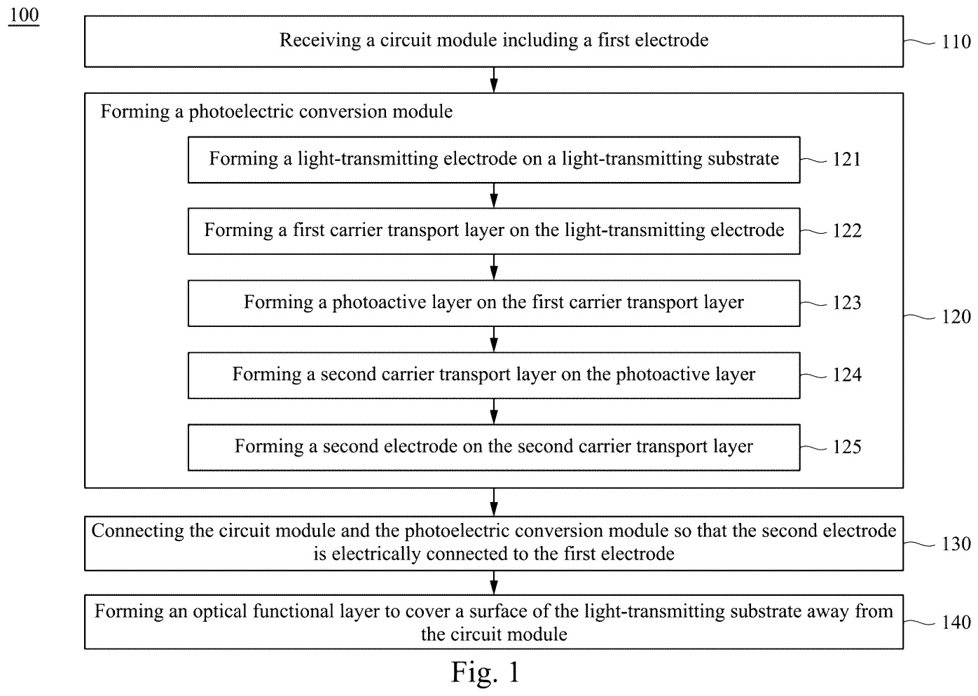

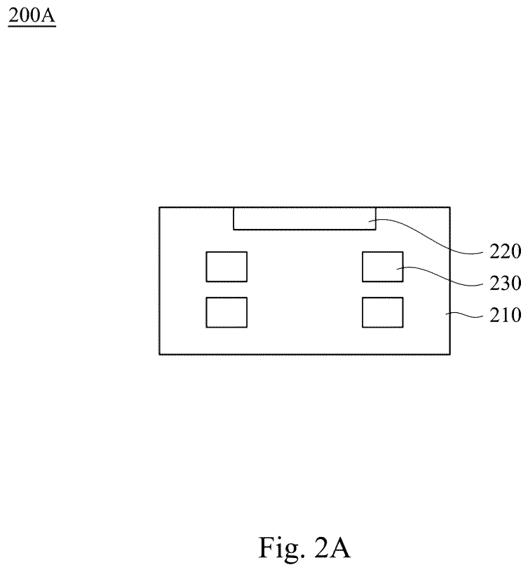

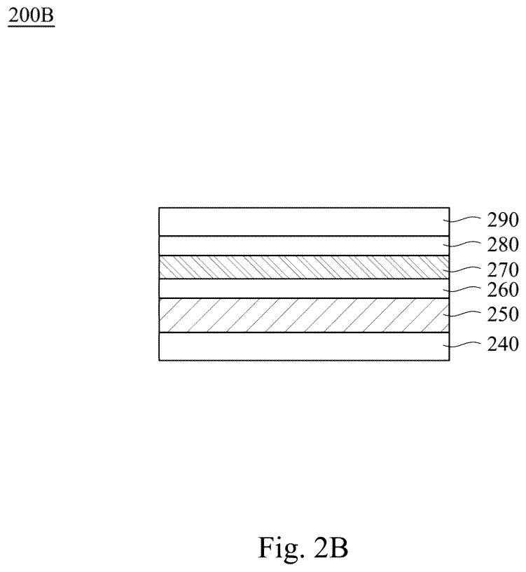

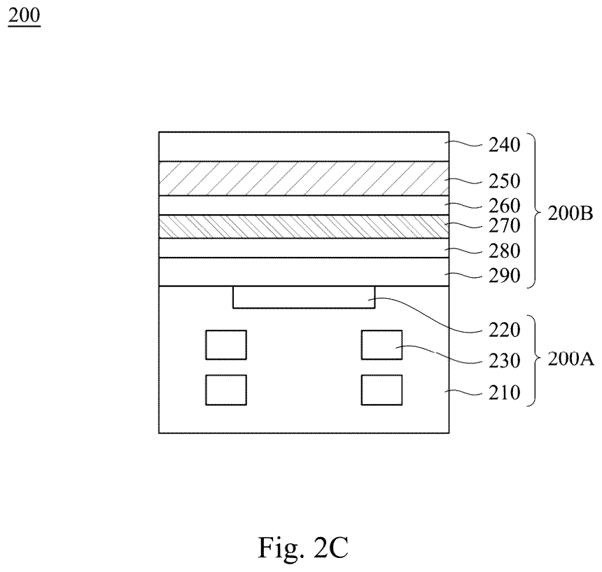

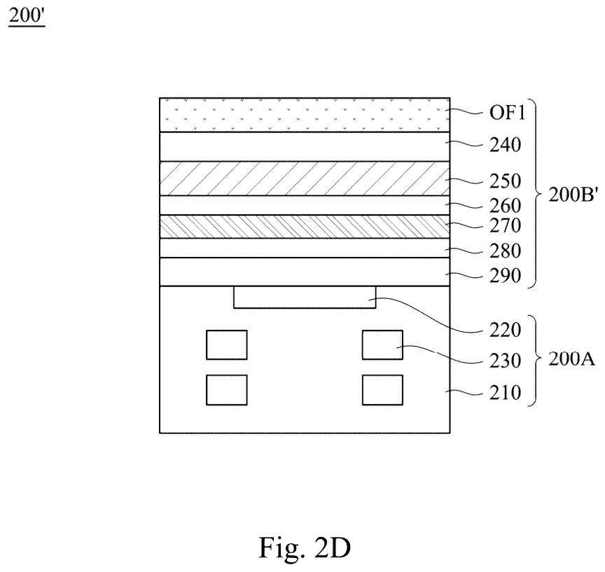

Please refer to FIG. 1 and FIGS. 2A to 2D at the same time. FIG. 1 is a flowchart of a method 100 of manufacturing a photoelectric device module according to various embodiments of the present disclosure. The method 100 includes operation 110, operation 120, operation 130, and operation 140. FIGS. 2A to 2D are schematic cross-sectional views of intermediate stages of manufacturing a photoelectric device module according to various embodiments of the present disclosure. Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all illustrated operations, steps, and/or features to achieve the embodiments of the present disclosure. In addition, each operation or step described herein may contain several sub-steps or actions.

In operation 110, as shown in FIG. 2A, a circuit module 200A including a first electrode 220 is received. In more detail, the circuit module 200A includes a circuit substrate 210, the first electrode 220, and a circuit 230. The first electrode 220 and the circuit 230 are embedded in the circuit substrate 210 and are electrically connected to each other. In some embodiments, the upper surface of the first electrode 220 is substantially aligned with the upper surface of circuit substrate 210. In other embodiments, a portion of first electrode 220 protrudes from the circuit substrate 210 (not shown).

Please continue to refer to FIG. 2A. In some embodiments, the circuit substrate 210 is a silicon wafer substrate, a glass substrate, a polymer substrate, or a ceramic substrate. In some embodiments, a material of the polymer substrate includes polyimide (PI), polyethylene terephthalate (PET), polyethylene naphthalate (PEN), polycarbonate (PC), or combinations thereof. In some embodiments, the first electrode 220 and the circuit 230 respectively include a metal, an alloy, a metal nitride, a metal oxide, a conductive polymer, a conductive carbon, or combinations thereof. In some embodiments, the first electrode 220 and the circuit 230 respectively include copper, silver, gold, aluminum, tungsten, molybdenum, titanium, titanium nitride, indium tin oxide (ITO), indium zinc oxide (IZO), graphene, carbon nanotubes, poly(3,4-ethylenedioxythiophene) polystyrene sulfonate (PEDOT:PSS), or combinations thereof. The first electrode 220 includes, for example, silver nanowires. In some embodiments, the first electrode 220 is a metal electrode.

In operation 120, as shown in FIG. 2B, a photoelectric conversion module 200B is formed. In more detail, operation 120 includes operation 121, operation 122, operation 123, operation 124, and operation 125.

In operation 121, a light-transmitting electrode 250 is formed on a light-transmitting substrate 240. In some embodiments, the light-transmitting substrate 240 and/or the light-transmitting electrode 250 allow visible light, near-infrared light, and/or short-wave infrared (SWIR) light to pass through. In more detail, the light-transmitting substrate 240 and/or the light-transmitting electrode 250 can be penetrated by light with a wavelength of 360 nm to 2500 nm, such as 360, 400, 440, 480, 520, 560, 600, 640, 680, 720, 760, 800, 840, 880, 920, 960, 1000, 1500, 2000, or 2500 nm. In some embodiments, a material of the light-transmitting substrate 240 includes polyimide (PI), polyethylene terephthalate (PET), polyethylene naphthalate (PEN), polycarbonate (PC), silicon, or combinations thereof. For example, the light-transmitting substrate 240 is a silicon wafer that can be penetrated by short-wave infrared light. In more detail, light with a wavelength from 1200 nm to 2500 nm can penetrate the silicon wafer. In some embodiments, the light-transmitting substrate 240 is a transparent substrate that allows visible light and near-infrared light to pass through. In some embodiments, a material of the light-transmitting electrode 250 includes a transparent metal oxide, a transparent conductive polymer, a conductive carbon, metal nanowires, or combinations thereof. For example, the material of the light-transmitting electrode 250 includes indium tin oxide (ITO), indium zinc oxide (IZO), PEDOT:PSS, graphene, carbon nanotubes, silver nanowires, or combinations thereof. In some embodiments, the light-transmitting electrode 250 is a transparent electrode that allows visible light, near-infrared light, and short-wave infrared light to pass through. In some embodiments, when the light-transmitting electrode 250 includes the transparent metal oxide, the light-transmitting electrode 250 is deposited on the light-transmitting substrate 240 by sputtering or electron beam evaporation. In some embodiments, when the light-transmitting electrode 250 includes the transparent conductive polymer, the conductive carbon, the metal nanowires, or combinations thereof, the light-transmitting electrode 250 can be formed on the light-transmitting substrate 240 by coating or printing.

In operation 122, a first carrier transport layer 260 is formed on the light-transmitting electrode 250. In operation 123, a photoactive layer 270 is formed on the first carrier transport layer 260. The photoactive layer 270 can be used for photoelectric conversion and photoelectric conduction. In some embodiments, the photoactive layer 270 includes an organic semiconductor, an inorganic semiconductor, a quantum dot, perovskite, or combinations thereof. In some embodiments, the quantum dot includes CdSe, CdZnS, CdSeS, CdS, ZnSe, InP, InS, CdTe, CuInS₂, CuInZnS, ZnS, PbS, PbSe, AgInS₂, Ag₂Te, InAs, Cd₃As₂, AgBiS₂, In(As,P), InGaP, or combinations thereof. In some embodiments, the perovskite has the following general formula: ABX₃, where A is an organic cation, B is a metal cation, and X is a halogen anion. In some embodiments, the perovskite includes CH₃NH₃PbI₃, CH₃NH₃PbBr₃, (MeNH₃)PbBr₃, Cs₂Sn₃I₆, Ag₃BiI₆, (CH₃NH₃)₃Bi₂Cl₉, Cs₂SnI₅Br, Cs₂TiBr₆, or combinations thereof.

In some embodiments, the organic semiconductor includes one or more P-type organic semiconductors and one or more N-type organic semiconductors. For example, the P-type organic semiconductors include:

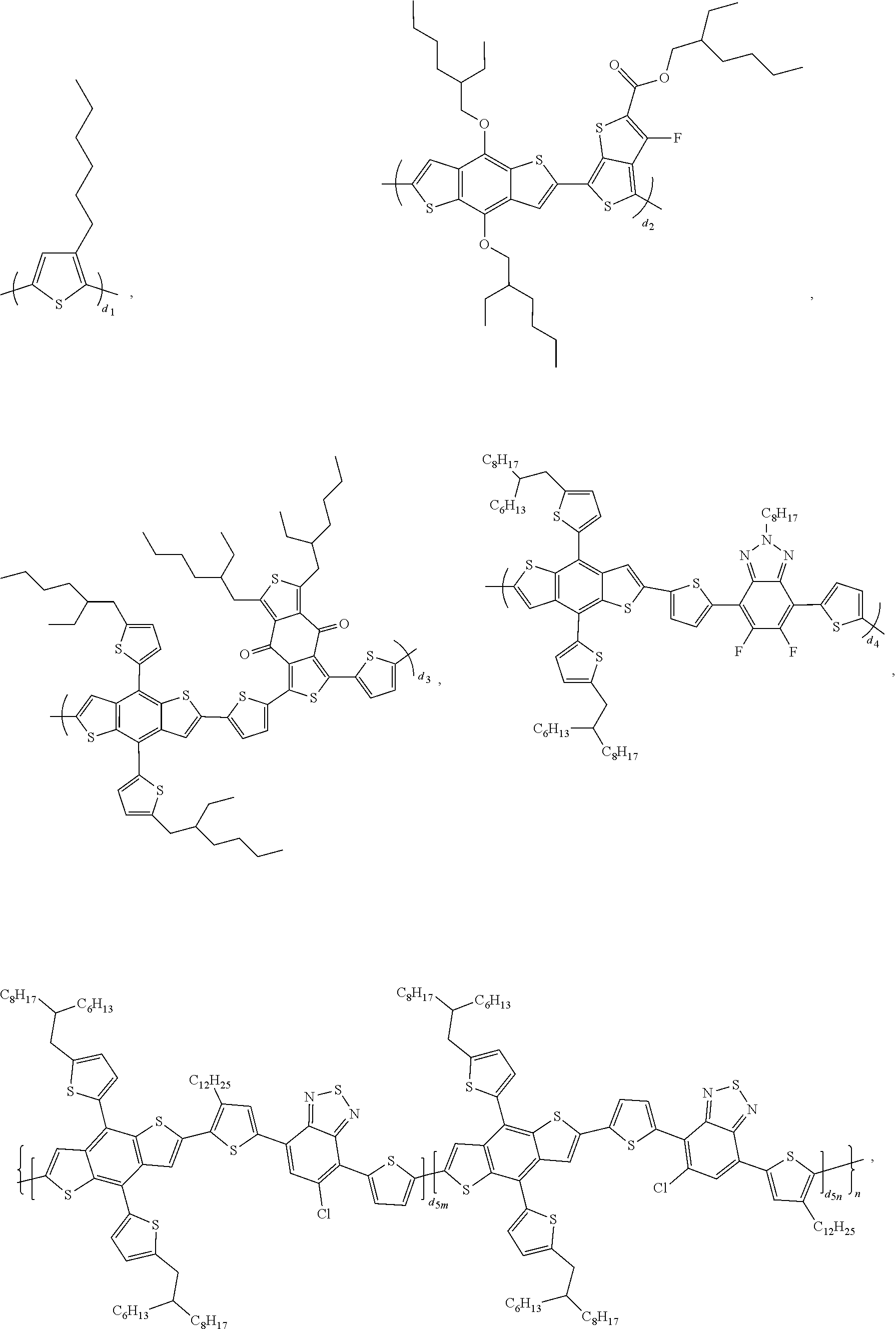

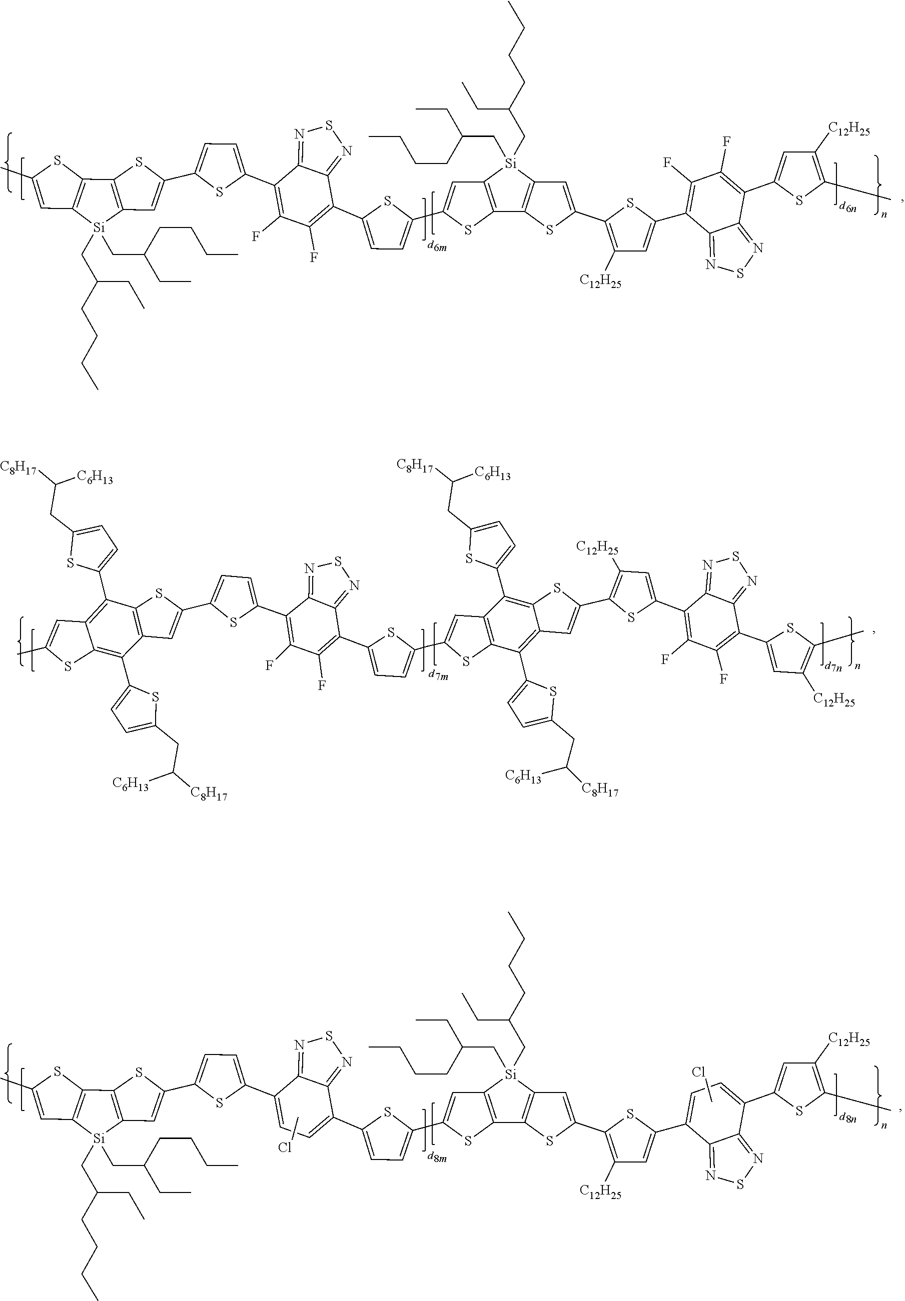

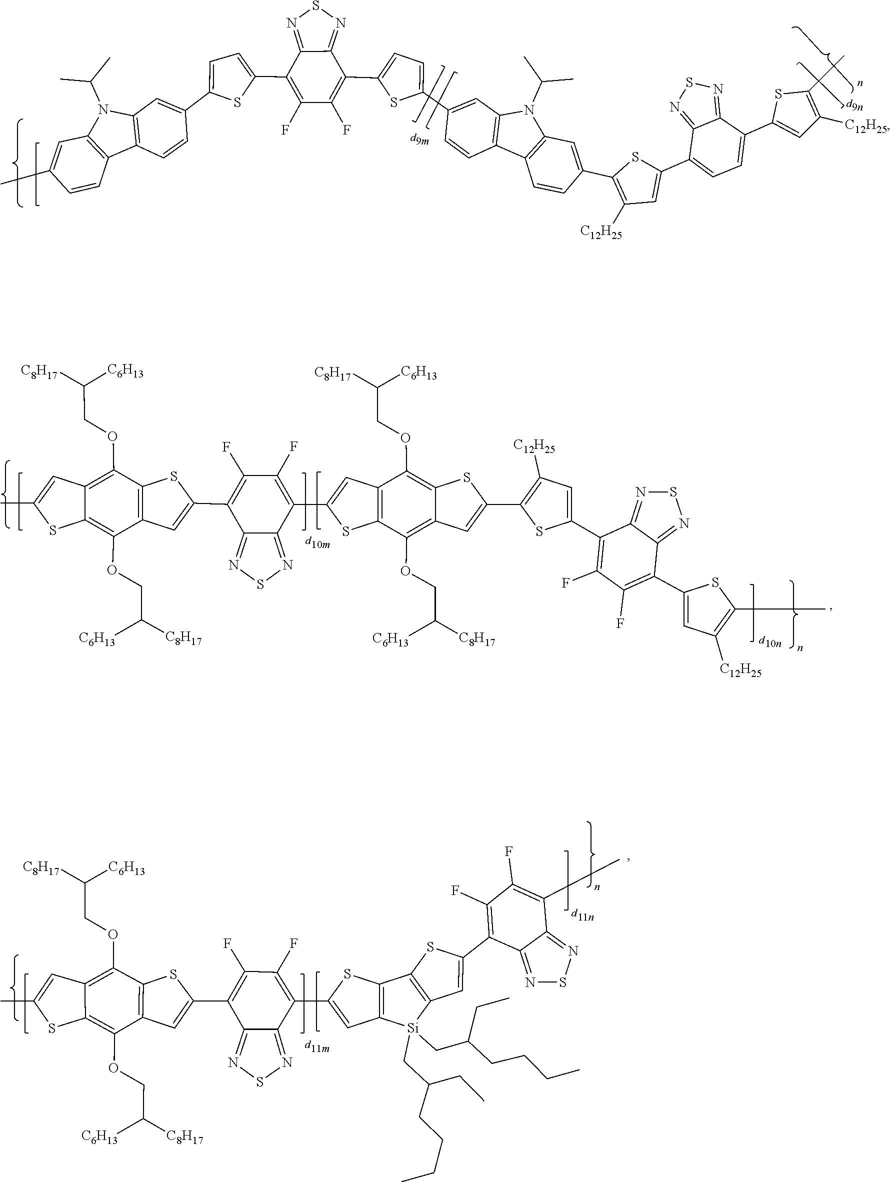

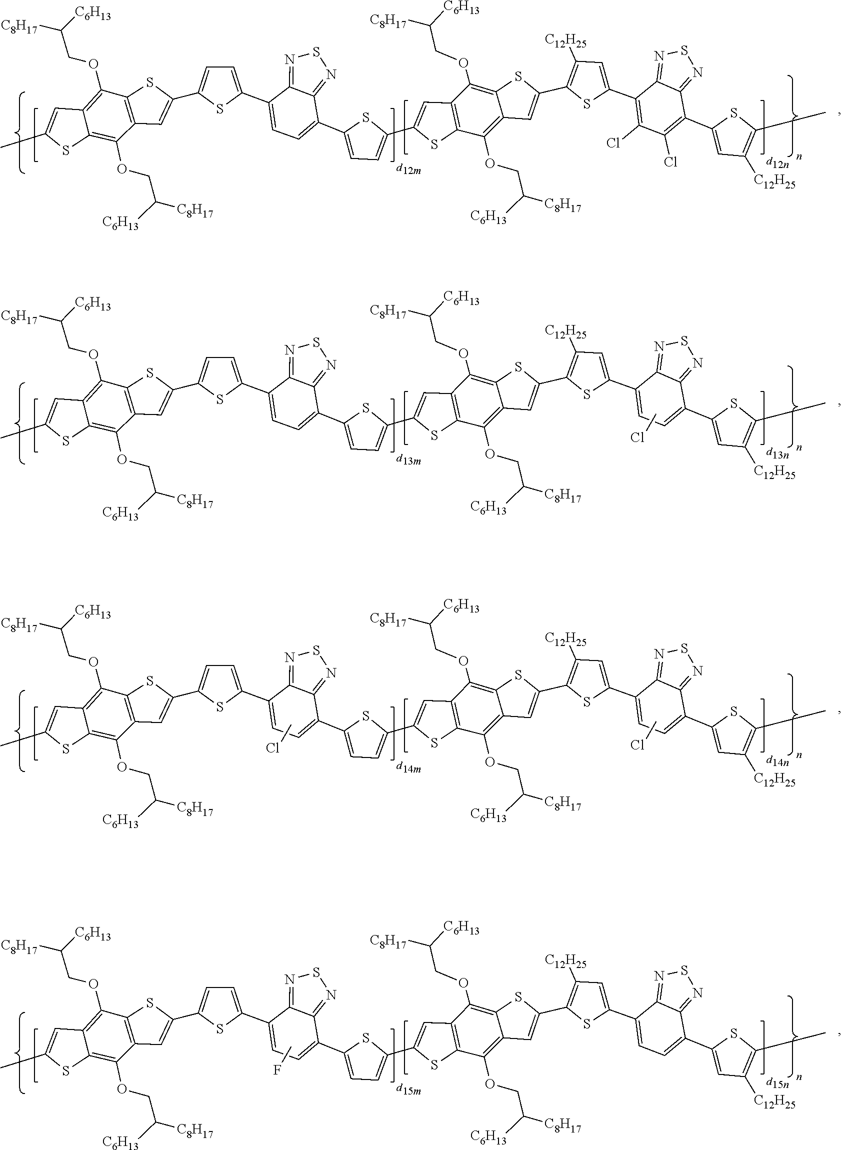

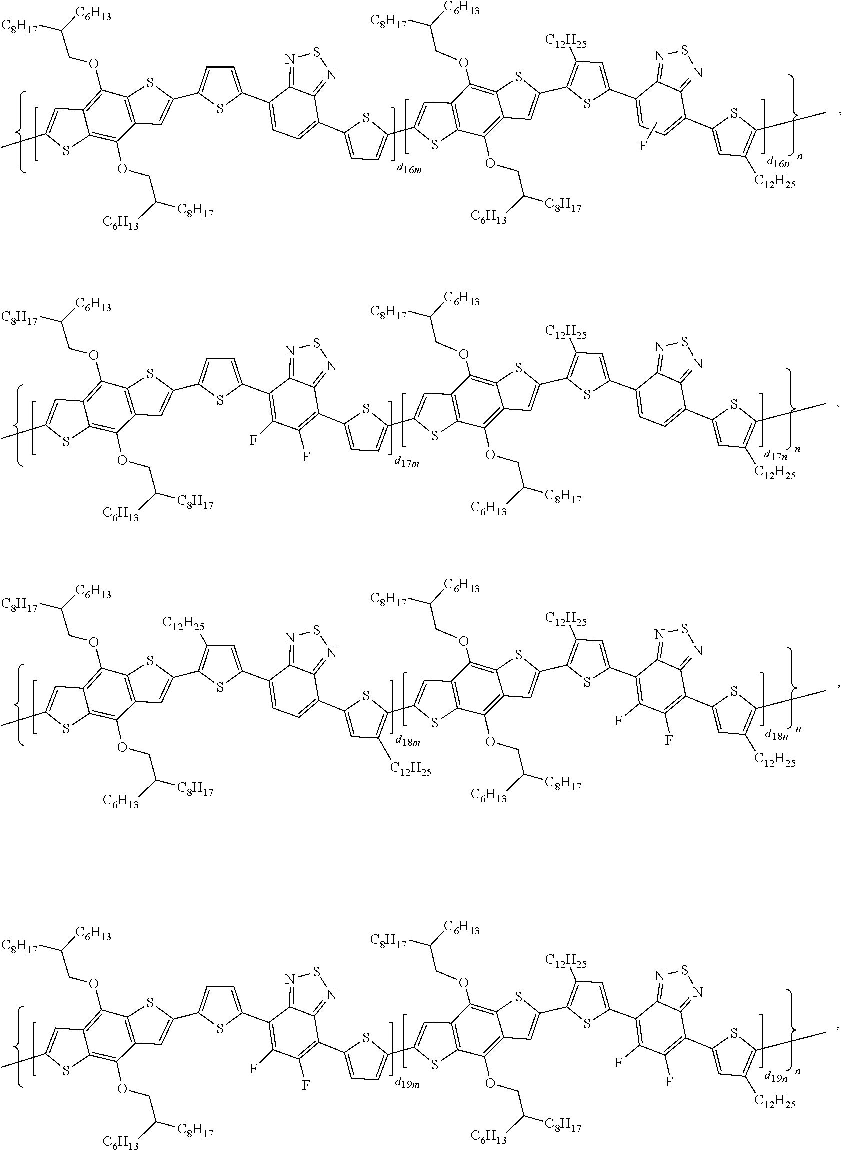

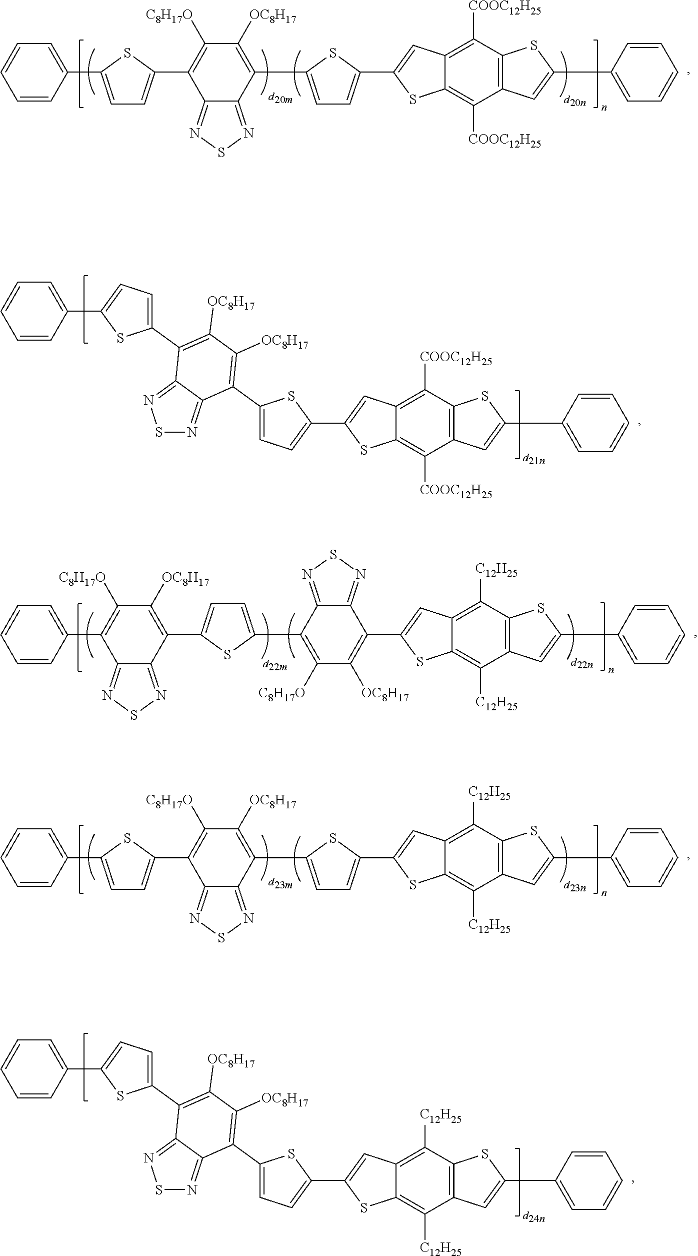

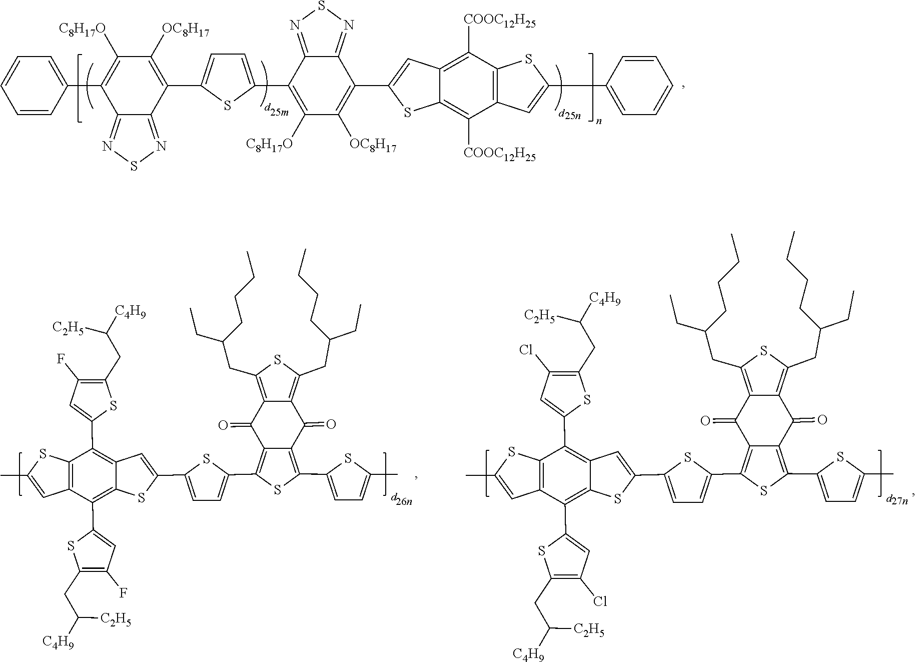

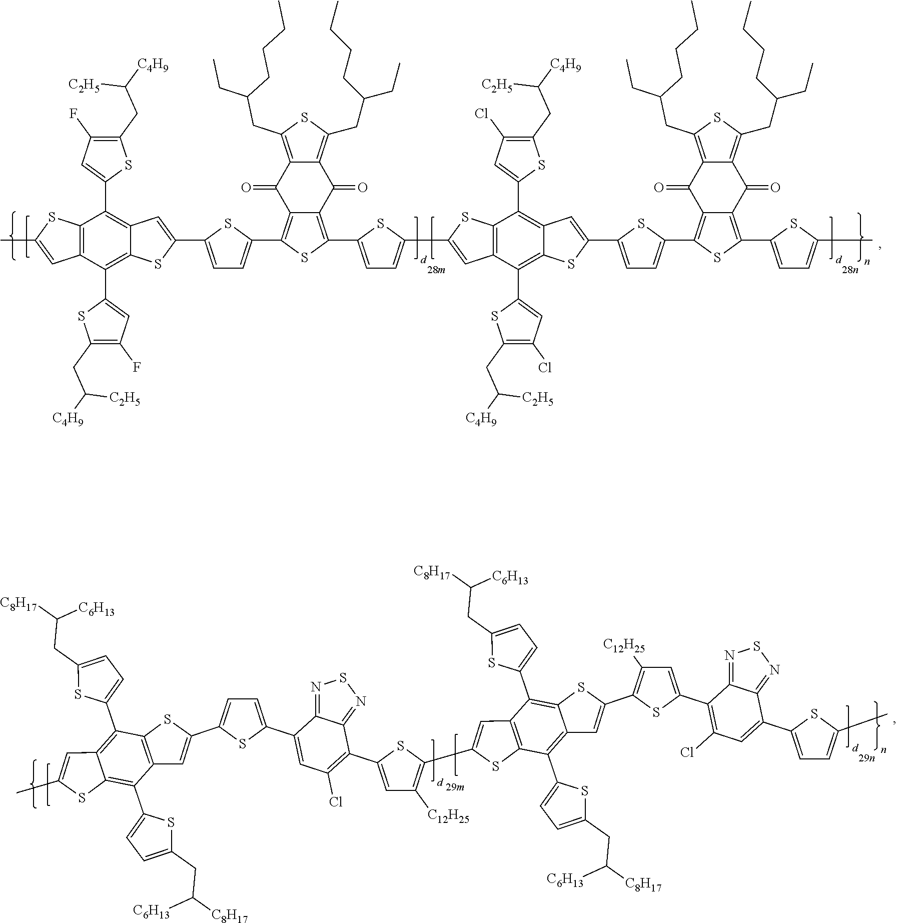

or combinations thereof. In the above P-type organic semiconductors, n, d₁, d₂, d₃, d₄, d₂₁ₙ, d₂₄ₙ, d₂₆ₙ, and d₂₇ₙ respectively and independently are a positive integer of 1-1000. d₅ₘ, d₅ₙ, d₆ₘ, d₆ₙ, d₇ₘ, d₇ₙ, d₈ₘ, d₈ₙ, d₉ₘ, d₉ₙ, d₁₀ₘ, d₁₀ₙ, d₁₁ₘ, d₁₁ₙ, d₁₂ₘ, d₁₂ₙ, d₁₃ₘ, d₁₃ₙ, d₁₄ₘ, d₁₄ₙ, d₁₅ₘ, d₁₅ₙ, d₁₆ₘ, d₁₆ₙ, d₁₇ₘ, d₁₇ₙ, d₁₈ₘ, d₁₈ₙ, d₁₉ₘ, d₁₉ₙ, d₂₀ₘ, d₂₀ₙ, d₂₂ₘ, d₂₂ₙ, d₂₃ₘ, d₂₃ₙ, d₂₅ₘ, d₂₅ₙ, d₂₈ₘ, d₂₈ₙ, d₂₉ₘ, and d₂₉ₙ respectively represent a mole fraction and respectively are greater than 0 and less than 1. The sum of d₅ₘ and d₅ₙ is 1. The sum of d₆ₘ and don is 1. The sum of d₇ₘ and d₇ₙ is 1. The sum of d₈ₘ and d₈ₙ is 1. The sum of d₉ₘ and d₉ₙ is 1. The sum of d₁₀ₘ and d₁₀ₙ is 1. The sum of d₁₁ₘ and d₁₁ₙ is 1. The sum of d₁₂ₘ and d₁₂ₙ is 1. The sum of d₁₃ₘ and d₁₃ₙ is 1. The sum of d₁₄ₘ and d₁₄ₙ is 1. The sum of d₁₅ₘ and d₁₅ₙ is 1. The sum of d₁₆ₘ and d₁₆ₙ is 1. The sum of d₁₇ₘ and d₁₇ₙ is 1. The sum of d₁₈ₘ and d₁₈ₙ is 1. The sum of d₁₉ₘ and d₁₉ₙ is 1. The sum of d₂₀ₘ and d₂₀ₙ is 1. The sum of d₂₂ₘ and d₂₂ₙ is 1. The sum of d₂₃ₘ and d₂₃ₙ is 1. The sum of d₂₅ₘ and d₂₅ₙ is 1. The sum of d₂₈ₘ and d₂₈ₙ is 1. The sum of d₂₉ₘ and d₂₉ₙ is 1. For example, the N-type organic semiconductors include:

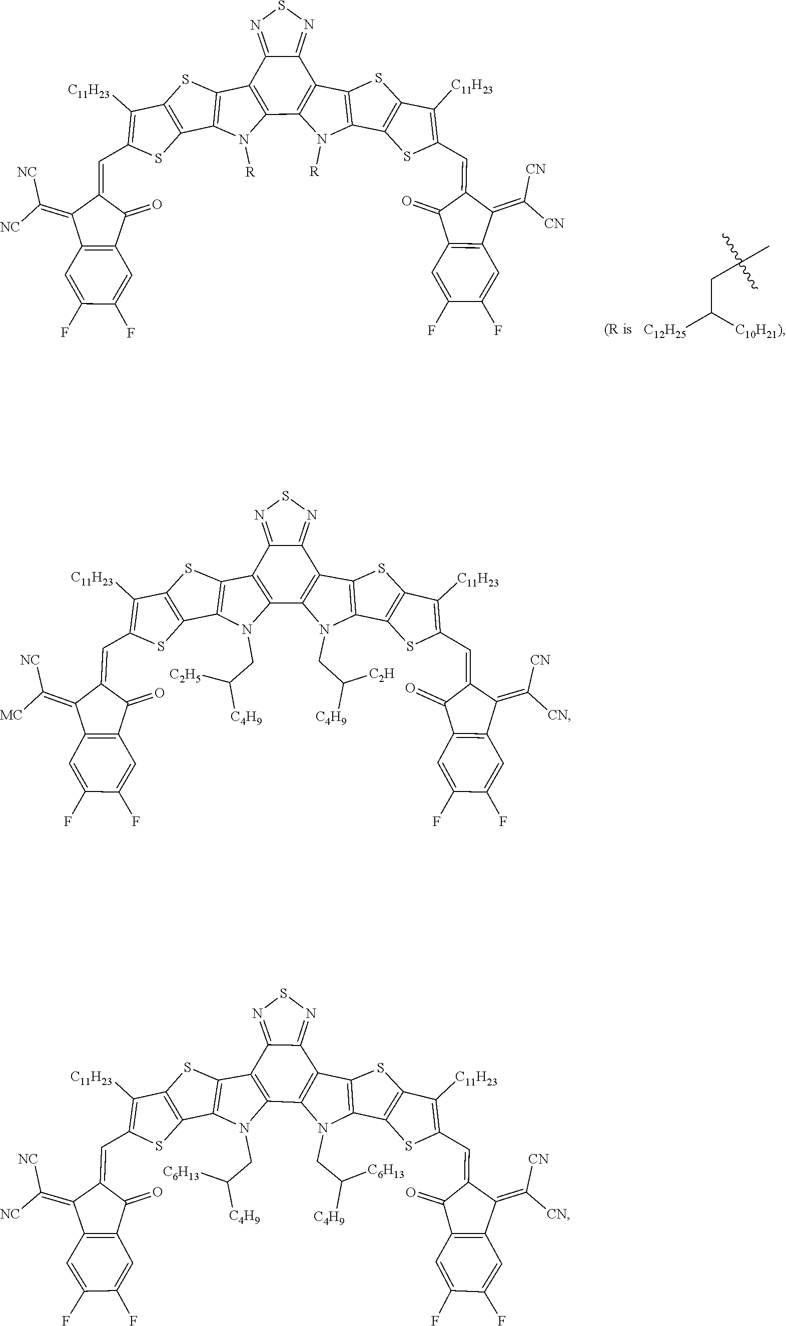

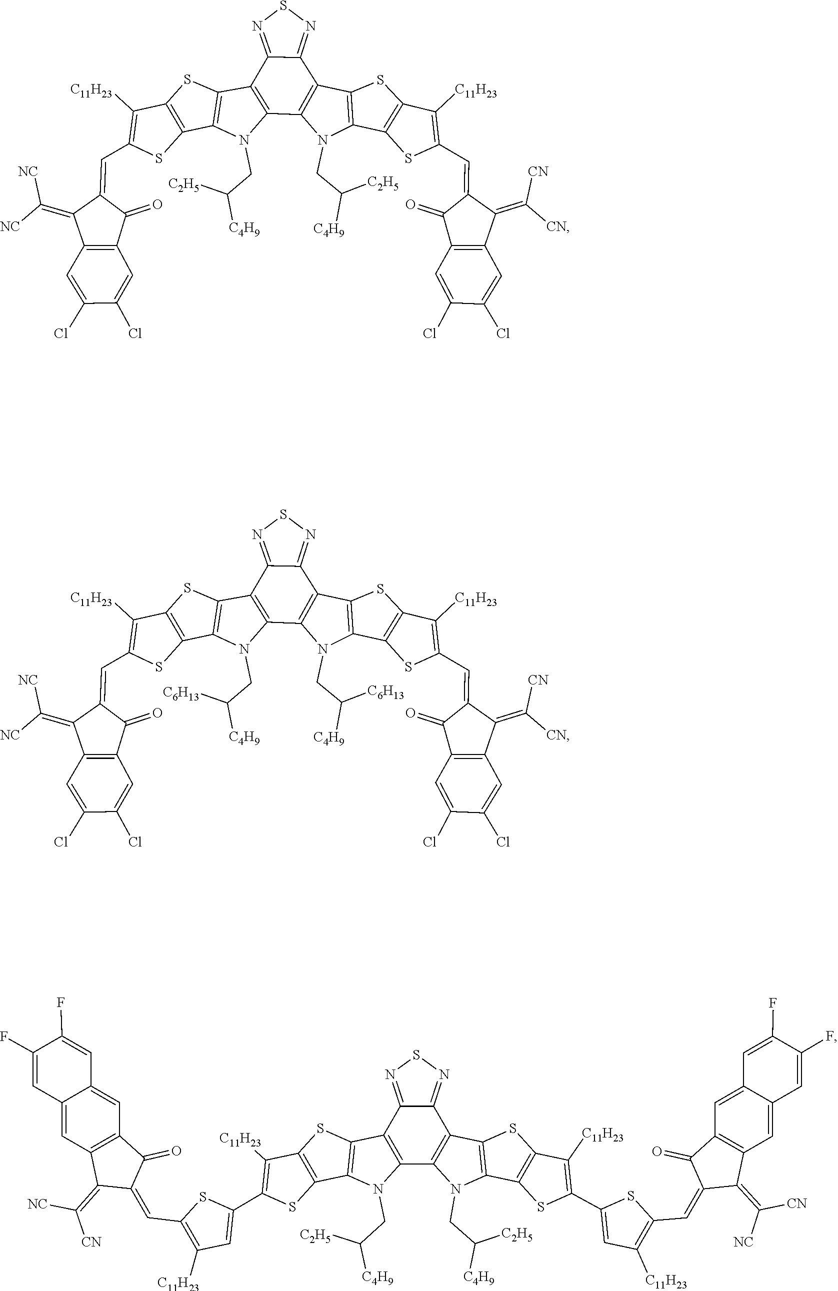

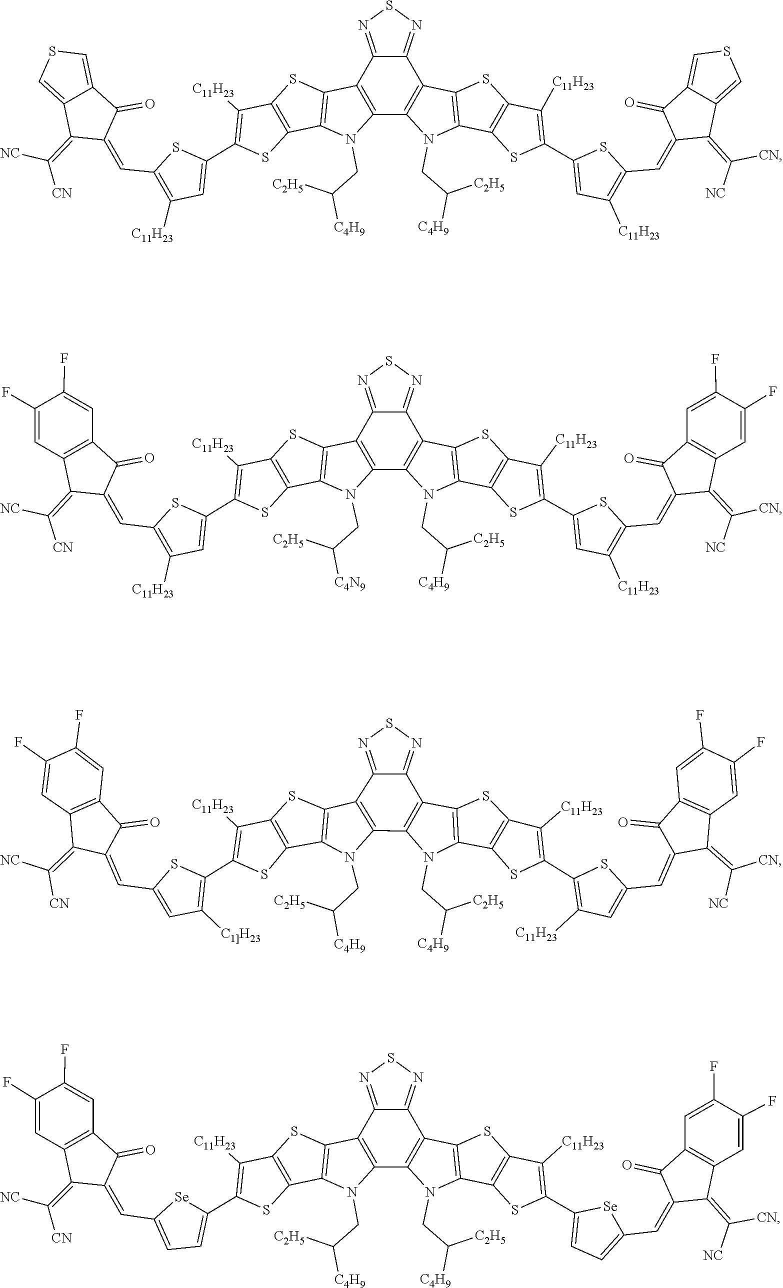

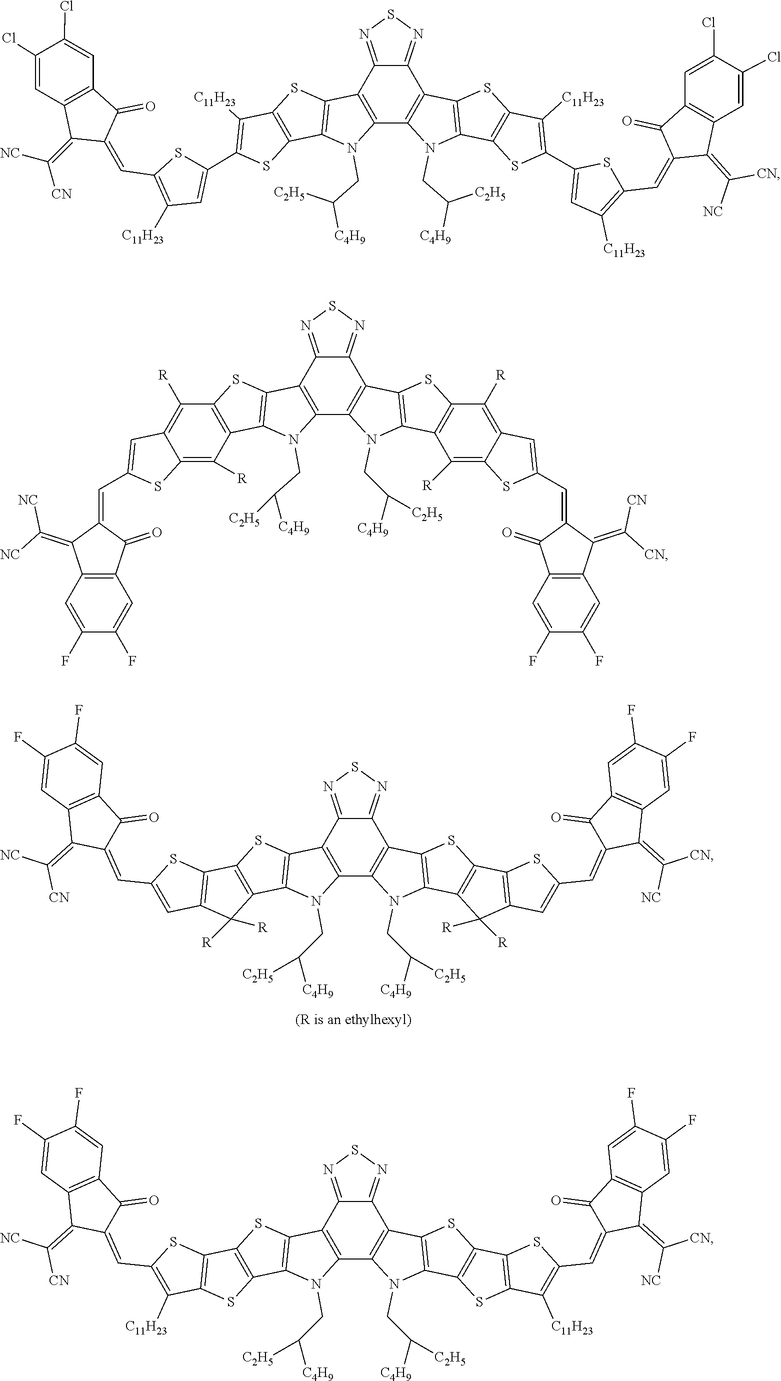

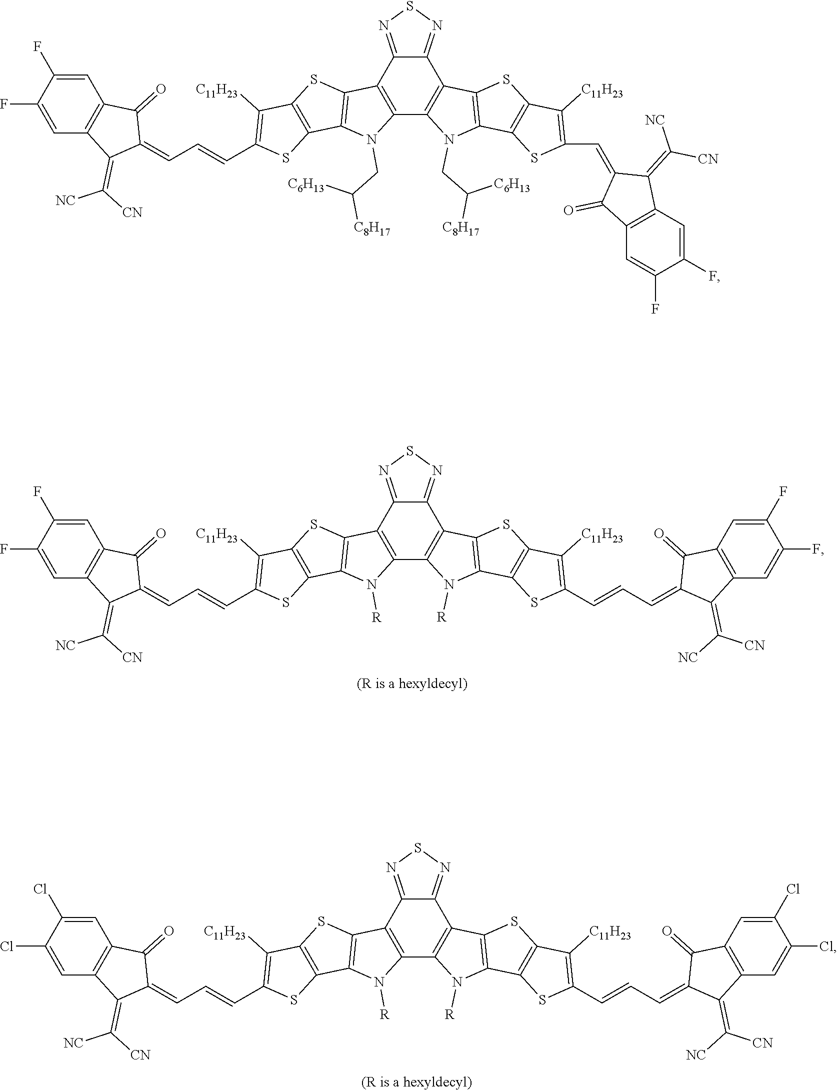

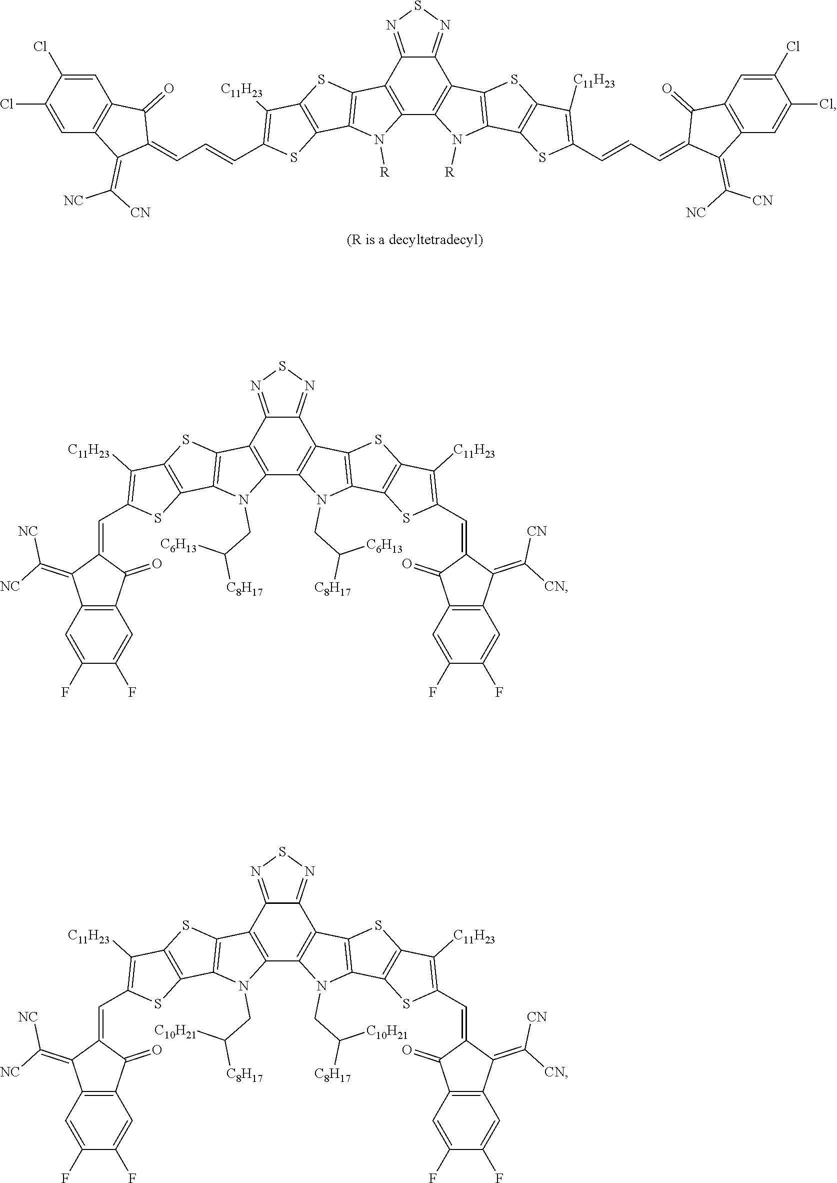

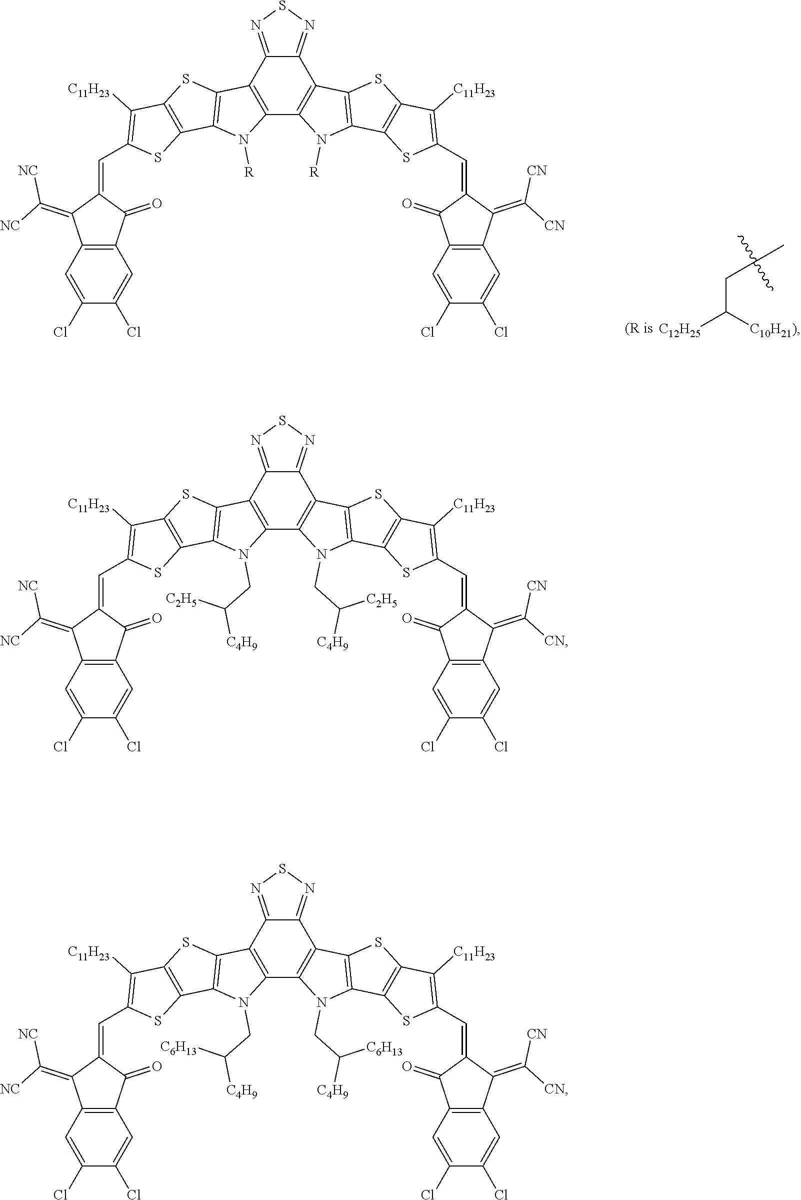

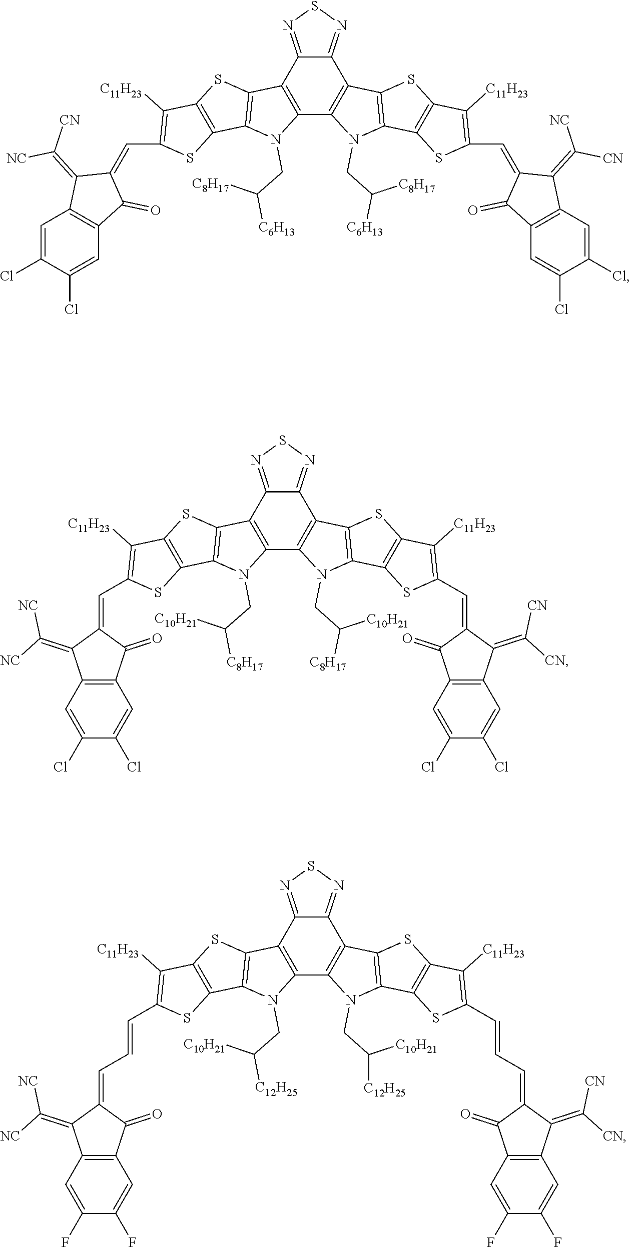

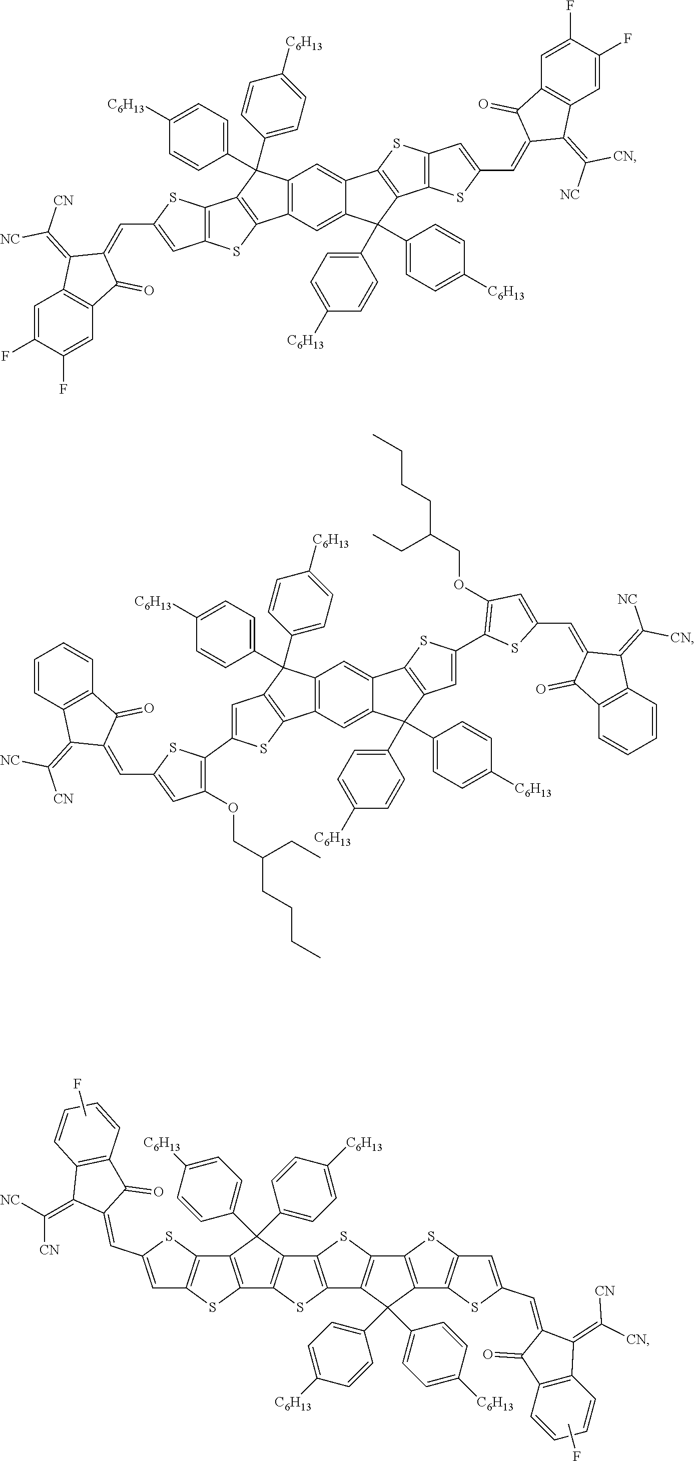

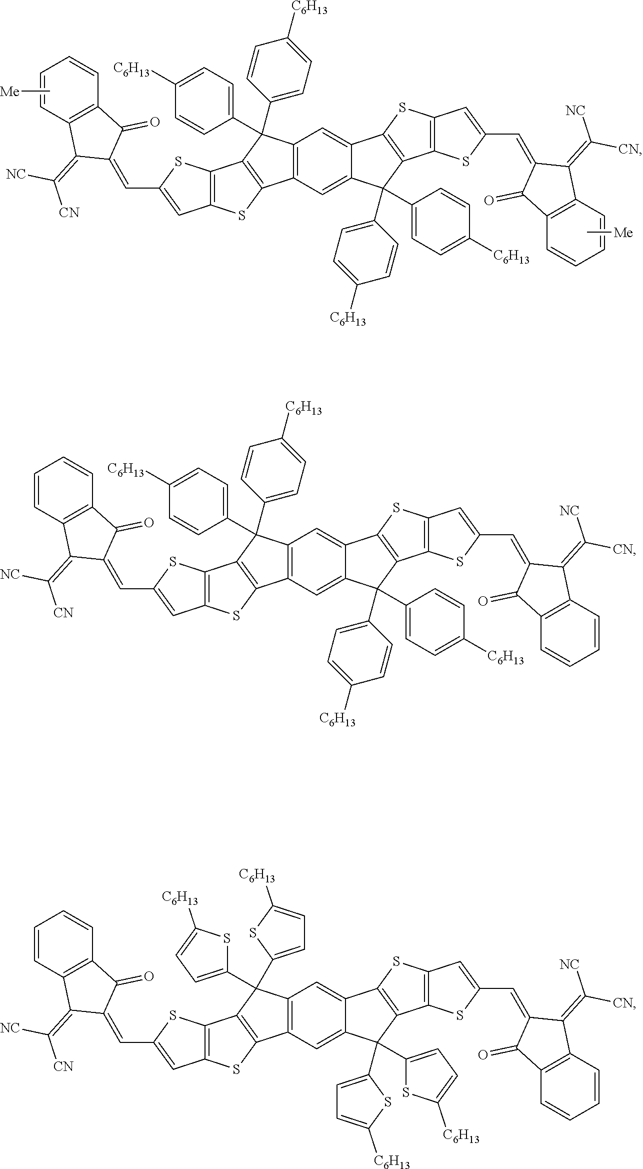

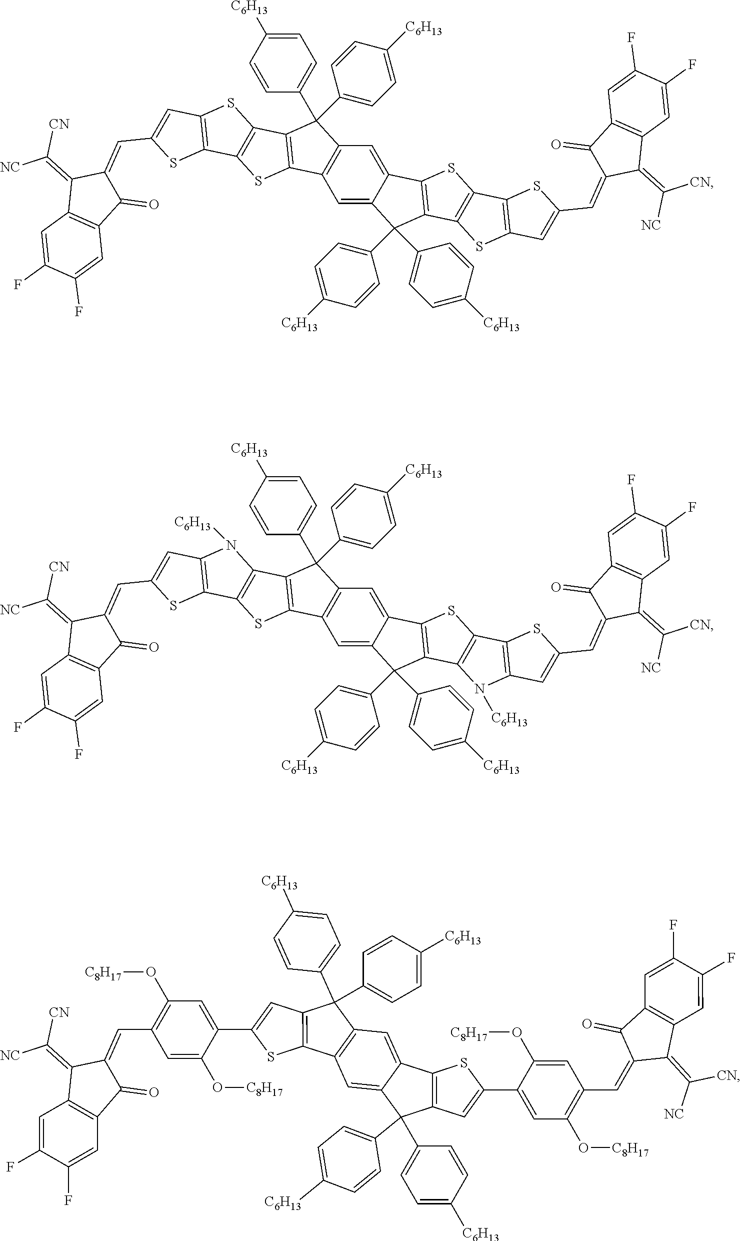

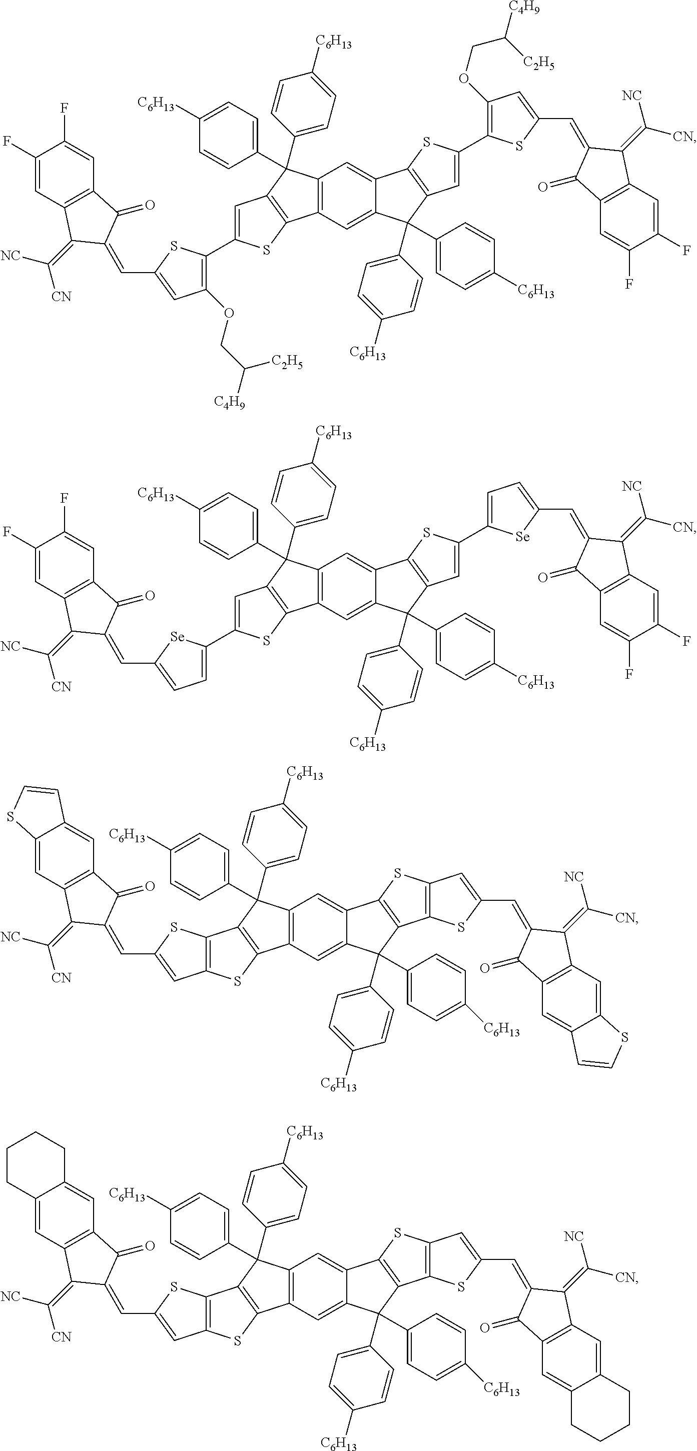

or combinations thereof.

In operation 124, a second carrier transport layer 280 is formed on the photoactive layer 270. The materials of the first carrier transport layer 260 and the second carrier transport layer 280 are different. In some embodiments, between the first carrier transport layer 260 and the second carrier transport layer 280, one is an electron transport layer and the other is a hole transport layer. For example, the first carrier transport layer 260 is an electron transport layer, and the second carrier transport layer 280 is a hole transport layer. For example, the first carrier transport layer 260 is a hole transport layer, and the second carrier transport layer 280 is an electron transport layer. In some embodiments, the electron transport layer includes aluminum-doped zinc oxide, zinc oxide, titanium oxide (e.g., titanium dioxide), tin oxide (e.g., tin dioxide), polyelectrolyte, or combinations thereof. In some embodiments, the hole transport layer includes molybdenum trioxide (MoO₃), nickel oxide (NiO), tungsten trioxide (WO₃), PEDOT:PSS, or combinations thereof.

In operation 125, a second electrode 290 is formed on the second carrier transport layer 280, thereby forming the photoelectric conversion module 200B. The photoelectric conversion module 200B includes the light-transmitting substrate 240, the light-transmitting electrode 250, the first carrier transport layer 260, the photoactive layer 270, the second carrier transport layer 280, and the second electrode 290 stacked in sequence. In some embodiments, the second electrode 290 includes a metal, an alloy, a metal nitride, a metal oxide, a conductive polymer, a conductive carbon, or combinations thereof. In some embodiments, the second electrode 290 includes copper, silver, gold, aluminum, tungsten, molybdenum, titanium, titanium nitride, indium tin oxide (ITO), indium zinc oxide (IZO), graphene, carbon nanotubes, poly(3,4-ethylenedioxythiophene) polystyrene sulfonate (PEDOT:PSS), or combinations thereof. The second electrode 290 includes, for example, silver nanowires. In some embodiments, the second electrode 290 is a metal electrode.

Please refer to FIG. 1 and FIG. 2B again. In other embodiments, operation 122 is omitted, so the photoactive layer 270 is formed on the light-transmitting electrode 250 during the manufacturing process of the photoelectric conversion module 200B. In some embodiments, the photoactive layer 270 is in direct contact with the light-transmitting electrode 250. In other embodiments, operation 124 is omitted, so the second electrode 290 is formed on the photoactive layer 270 during the manufacturing process of the photoelectric conversion module 200B. In some embodiments, the second electrode 290 is in direct contact with the photoactive layer 270.

In operation 130, as shown in FIG. 2C, the circuit module 200A and the photoelectric conversion module 200B are connected so that the second electrode 290 is electrically connected to the first electrode 220, thereby forming a photoelectric device module 200. In more detail, the first electrode 220 is in direct contact with the second electrode 290. In some embodiments, the first electrode 220 and the second electrode 290 form an Ohmic junction. The circuit module 200A and the photoelectric conversion module 200B can be connected to each other through chemical bonding or physical bonding. In some embodiments, connecting the circuit module 200A and the photoelectric conversion module 200B is performed by bonding, adhering, or welding. For example, the circuit module 200A and the photoelectric conversion module 200B can be welded to each other through a conductive block (not shown). For example, the circuit module 200A and the photoelectric conversion module 200B can be adhered or welded by conductive paste (such as silver paste). For example, the circuit module 200A and the photoelectric conversion module 200B can be connected to each other by solid-state welding (such as cold welding). The first electrode 220 can receive a signal generated by the photoelectric conversion module 200B or transmit a signal to the photoelectric conversion module 200B. As shown in FIG. 2C, the light-transmitting substrate 240 can be used as part of a packaging structure for packaging the photoelectric device module 200. Therefore, compared with other processes that require the formation of an additional encapsulation layer on the upper surface of the photoelectric device module, the process of the present disclosure can prevent the high temperature, plasma bombardment, and/or acidity and alkalinity of reactants used to manufacture the encapsulation layer from damaging the components or materials in the photoelectric device module 200. In addition, compared with other materials, using a glass substrate or a silicon substrate as the light-transmitting substrate 240 can achieve the best packaging effect. In addition, the substrate can be further thinned based on design requirements.

Please continue to refer to FIG. 2C. If the light-transmitting electrode 250 is directly formed on the first carrier transport layer 260 and the photoactive layer 270 by a deposition process, such as evaporation, sputtering, or coating, the high temperature, plasma bombardment, and/or acidity and alkalinity of reactants in the deposition process may damage part of the photoelectric conversion module 200B. In addition, the process of depositing other films of the photoelectric conversion module 200B may also damage the circuit module 200A. However, the second electrode 290 of the photoelectric conversion module 200B of the present disclosure is connected to the first electrode 220 of the circuit module 200A through a connection process, thereby preventing evaporation, sputtering, coating, and other processes from damaging the components in the circuit module 200A, such as the first electrode 220.

In operation 140, as shown in FIG. 2D, an optical functional layer OF1 is formed to cover the surface of the light-transmitting substrate 240 away from the circuit module 200A (i.e., the upper surface of the light-transmitting substrate 240), thereby forming a photoelectric device module 200′. In some embodiments, the optical functional layer OF1 includes a filter, an anti-reflection structure, a light-condensing structure, a structure for blocking water and oxygen, or combinations thereof. The filter is, for example, a color filter. The anti-reflection structure is, for example, an anti-reflection coating (ARC). The light-condensing structure is, for example, a plurality of convex lenses. The structure for blocking water and oxygen is, for example, a film for blocking water and oxygen. In some embodiments, the optical functional layer OF1 is formed on the light-transmitting substrate 240 through a coating process or a deposition process. When forming the optical functional layer OF1, the light-transmitting substrate 240 can protect the films below the light-transmitting substrate 240 from being affected by the process temperature of forming the optical functional layer OF1, thereby preventing damage or degradation of the films.

Please continue to refer to FIG. 2D. The photoelectric device module 200′ includes a circuit module 200A and a photoelectric conversion module 200B′. The circuit module 200A includes a circuit substrate 210, a first electrode 220, and a circuit 230. The photoelectric conversion module 200B′ is disposed on the circuit module 200A, in which the photoelectric conversion module 200B′ includes a second electrode 290, a second carrier transport layer 280, a photoactive layer 270, a first carrier transport layer 260, a light-transmitting electrode 250, a light-transmitting substrate 240, and an optical functional layer OF1. The second electrode 290 is electrically connected to the first electrode 220. The photoactive layer 270 is disposed on the second electrode 290 to cover the second electrode 290. The light-transmitting electrode 250 is disposed on the photoactive layer 270. The light-transmitting substrate 240 is disposed on the light-transmitting electrode 250. The optical functional layer OF1 is disposed on the light-transmitting substrate 240. The first carrier transport layer 260 is disposed between the light-transmitting electrode 250 and the photoactive layer 270. The second carrier transport layer 280 is disposed between the photoactive layer 270 and the second electrode 290. In other embodiments, the first carrier transport layer 260 is omitted, and therefore the light-transmitting electrode 250 is in direct contact with the photoactive layer 270. In other embodiments, the second carrier transport layer 280 is omitted, and therefore the photoactive layer 270 is in direct contact with the second electrode 290.

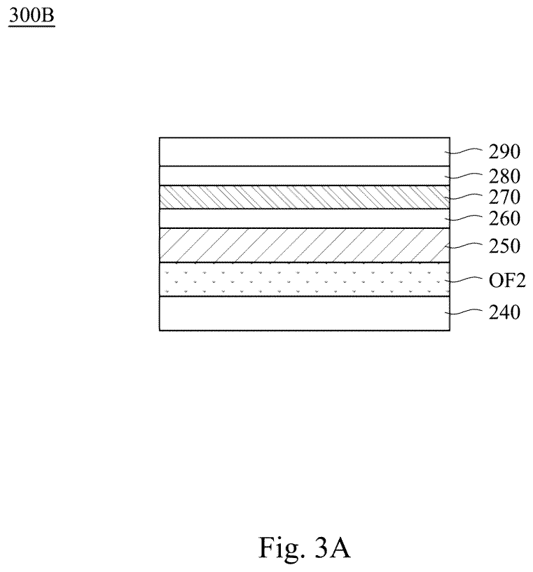

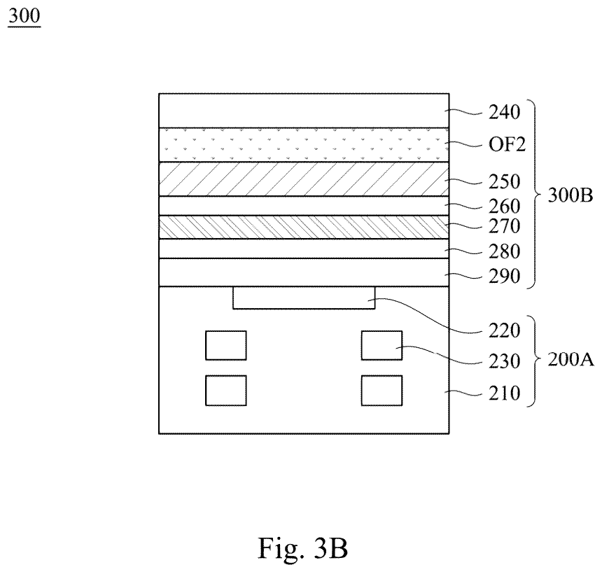

FIGS. 3A to 3B are schematic cross-sectional views of intermediate stages of manufacturing a photoelectric device module 300 according to various embodiments of the present disclosure. As shown in FIG. 3A, a photoelectric conversion module 300B is manufactured. Please refer to operation 120 of manufacturing the photoelectric conversion module 200B to manufacture the photoelectric conversion module 300B. The difference between the method of manufacturing the photoelectric conversion module 200B and the method of manufacturing the photoelectric conversion module 300B is that the method of manufacturing photoelectric conversion module 300B further includes: before forming the light-transmitting electrode 250 on the light-transmitting substrate 240, forming an optical functional layer OF2 to cover the upper surface of light-transmitting substrate 240. Next, as shown in FIG. 3B, please refer to operation 130 of manufacturing the photoelectric device module 200 to manufacture the photoelectric device module 300. In more detail, the circuit module 200A and the photoelectric conversion module 300B are connected so that the second electrode 290 is electrically connected to the first electrode 220. It is worth noting that a higher temperature (for example, higher than 160° C.) and a longer time are usually required to form the optical functional layer OF2. In the method of manufacturing the photoelectric device module 300 of the present disclosure, the temperature and time required to form the optical functional layer OF2 do not affect the properties of other films in the photoelectric conversion module 300B at all, thereby making the photoelectric device module 300 have excellent photoelectric conversion properties and reliability. For the embodiments of the optical functional layer OF2, please refer to the embodiments of the optical functional layer OF1, and they will not be described again.

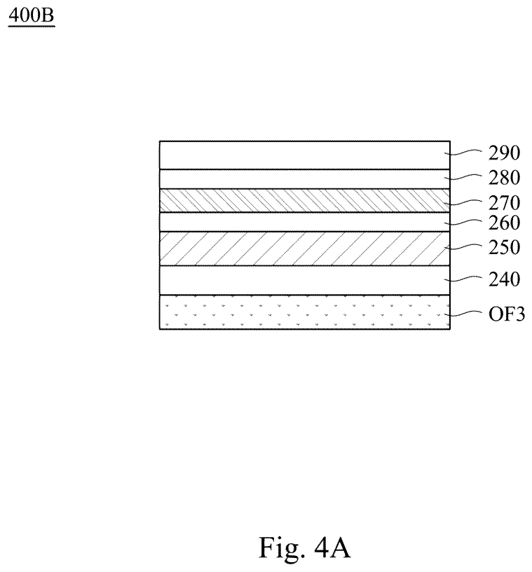

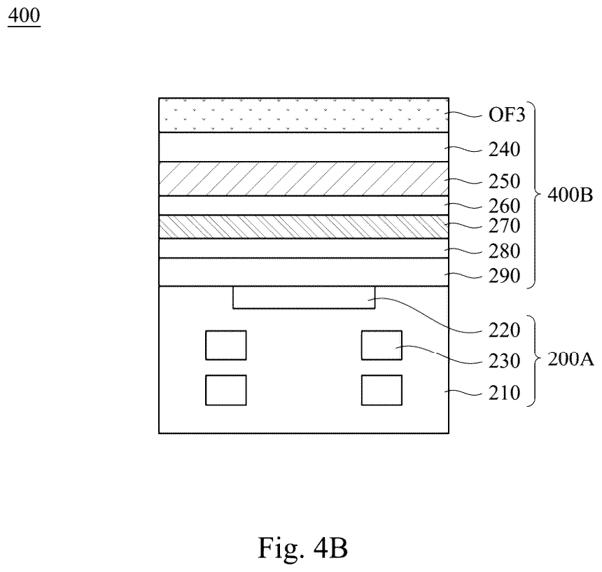

FIGS. 4A to 4B are schematic cross-sectional views of intermediate stages of manufacturing a photoelectric device module according to various embodiments of the present disclosure. As shown in FIG. 4A, a photoelectric conversion module 400B is manufactured. Please refer to operation 120 of manufacturing the photoelectric conversion module 200B to manufacture the photoelectric conversion module 400B. The difference between the method of manufacturing the photoelectric conversion module 200B and the method of manufacturing the photoelectric conversion module 400B is that the method of manufacturing the photoelectric conversion module 400B further includes: before or after forming the light-transmitting electrode 250 on the light-transmitting substrate 240, forming an optical functional layer OF3 to cover the lower surface of the light-transmitting substrate 240. Next, as shown in FIG. 4B, please refer to operation 130 of manufacturing the photoelectric device module 200 to manufacture the photoelectric device module 400. In more detail, the circuit module 200A and the photoelectric conversion module 400B are connected so that the second electrode 290 is electrically connected to the first electrode 220. It is worth noting that a higher temperature (for example, higher than 160° C.) and a longer time are usually required to form the optical functional layer OF3. In the method of manufacturing the photoelectric device module 400 of the present disclosure, the temperature and time required to form the optical functional layer OF3 do not affect the properties of other films in the photoelectric conversion module 400B, thereby making the photoelectric device module 400 have excellent photoelectric conversion properties and reliability. For the embodiments of the optical functional layer OF3, please refer to the embodiments of the optical functional layer OF1, and they will not be described again.

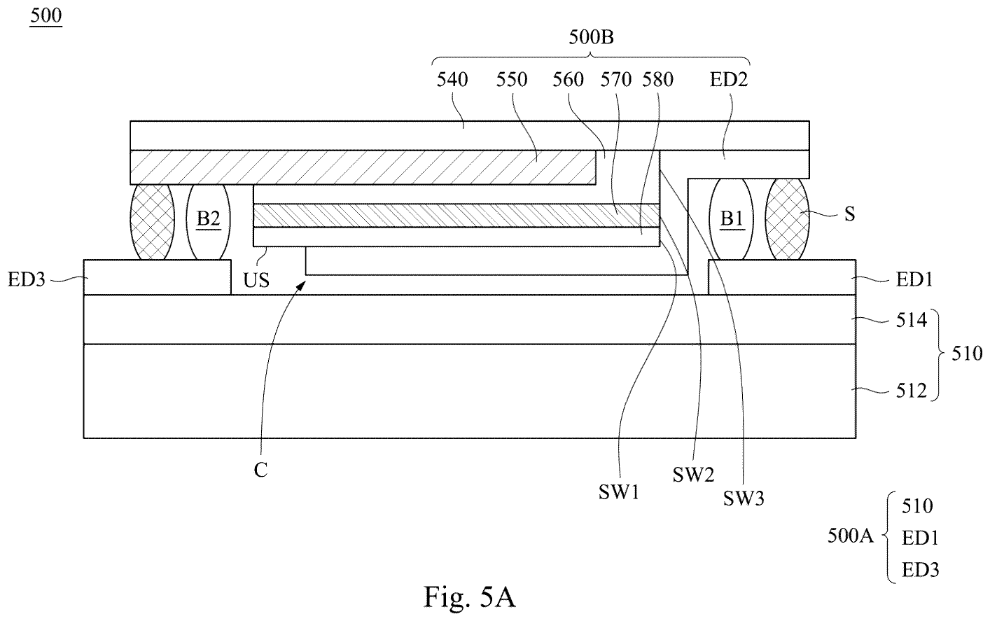

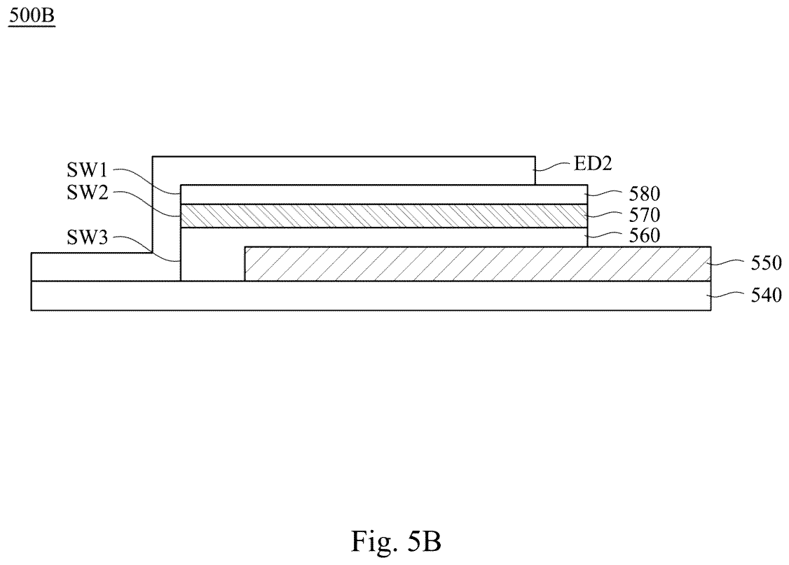

FIG. 5A is a schematic cross-sectional view of a photoelectric device module 500 according to various embodiments of the present disclosure. The photoelectric device module 500 includes a circuit module 500A and a photoelectric conversion module 500B disposed on the circuit module 500A. The circuit module 500A includes a circuit substrate 510 and a first electrode ED1, in which the circuit substrate 510 includes a substrate 512 and an insulating layer 514 located on the substrate 512, and the first electrode ED1 is disposed on the insulating layer 514. The photoelectric conversion module 500B includes a light-transmitting substrate 540, a light-transmitting electrode 550, a first carrier transport layer 560, a photoactive layer 570, a second carrier transport layer 580, and a second electrode ED2. The second electrode ED2 is electrically connected to the first electrode ED1. The photoactive layer 570 is disposed on the second electrode ED2 to cover the second electrode ED2. The light-transmitting electrode 550 is disposed on the photoactive layer 570. The light-transmitting substrate 540 is disposed on the light-transmitting electrode 550. The first carrier transport layer 560 is disposed between the light-transmitting electrode 550 and the photoactive layer 570. The second carrier transport layer 580 is disposed between the photoactive layer 570 and the second electrode ED2. In other embodiments, the first carrier transport layer 560 is omitted, and therefore the light-transmitting electrode 550 is in direct contact with the photoactive layer 570. In other embodiments, the second carrier transport layer 580 is omitted, and therefore the photoactive layer 570 is in direct contact with the second electrode ED2. For the formation methods, materials, and functions of the substrate 512, the light-transmitting substrate 540, the light-transmitting electrode 550, the first carrier transport layer 560, the photoactive layer 570, the second carrier transport layer 580, and the second electrode ED2, please refer to the formation methods, materials, and functions of the circuit substrate 210, the light-transmitting substrate 240, the light-transmitting electrode 250, the first carrier transport layer 260, the photoactive layer 270, the second carrier transport layer 280, and the second electrode 290, and they will not be described again.

Please continue to refer to FIG. 5A. The photoelectric device module 500 further includes a conductive block B1, in which the first electrode ED1 is electrically connected to the second electrode ED2 through the conductive block B1. The conductive block B1 is, for example, a solder bump. In other embodiments, the first electrode ED1 is in direct contact with the second electrode ED2 (not shown). As shown in FIG. 5A, the second electrode ED2 covers the lower surface US and the side surface SW1 of the second carrier transport layer 580, the side surface SW2 of the photoactive layer 570, and the side surface SW3 of the first carrier transport layer 560. As shown in FIG. 5A, the circuit module 500A further includes a third electrode ED3, and the third electrode ED3 is electrically connected to the light-transmitting electrode 550 through the conductive block B2. The conductive block B2 is, for example, a solder bump. In other embodiments, the light-transmitting electrode 550 is in direct contact with the third electrode ED3 (not shown). As shown in FIG. 5A, the photoelectric device module 500 further includes a sealant S, in which the sealant S is disposed between the edge of the photoelectric conversion module 500B and the edge of the circuit module 500A to encapsulate the photoelectric device module 500. In some embodiments, the sealant S, the photoelectric conversion module 500B, and the circuit module 500A surround a closed chamber C. In some embodiments, the sealant S includes epoxy resin. In some embodiments, the substrate 512 is a silicon wafer substrate, the first electrode ED1, the second electrode ED2, and the third electrode ED3 are metal electrodes, and the light-transmitting electrode 550 is an ITO electrode.

FIG. 5B is a schematic cross-sectional view of forming the photoelectric conversion module 500B of FIG. 5A. Please refer to operation 120 in FIG. 1 to manufacture the photoelectric conversion module 500B. In operation 121, the light-transmitting electrode 550 is formed on the light-transmitting substrate 540. In operation 122, the first carrier transport layer 560 is formed on the light-transmitting electrode 550. In operation 123, the photoactive layer 570 is formed on the first carrier transport layer 560. In operation 124, the second carrier transport layer 580 is formed on the photoactive layer 570. In operation 125, the second electrode ED2 is formed on the second carrier transport layer 580. More specifically, the second electrode ED2 is formed to cover the surface and the side surface SW1 of the second carrier transport layer 580, the side surface SW2 of the photoactive layer 570, and the side surface SW3 of the first carrier transport layer 560. Please refer to FIG. 5A again, and please refer to operation 130 of FIG. 1 to manufacture the photoelectric device module 500. The circuit module 500A and the photoelectric conversion module 500B are connected so that the second electrode ED2 is electrically connected to the first electrode ED1. The method of manufacturing the photoelectric device module 500 may further include: disposing the sealant S between the edge of the photoelectric conversion module 500B and the circuit module 500A to form the closed chamber C, which is surrounded by the sealant S, the photoelectric conversion module 500B, and the circuit module 500A.

Please refer to FIG. 5A again. Please refer to the embodiments of the photoelectric device module 200′, the photoelectric device module 300, or the photoelectric device module 400. The optical functional layer OF1, the optical functional layer OF2, or the optical functional layer OF3 can be further disposed in the photoelectric device module 500.

The following describes the features of the present disclosure more specifically with reference to Experimental Examples 1 to 2. Although the following experimental examples are described, the materials, their amounts and ratios, processing details, processing procedures, etc., may be appropriately varied without exceeding the scope of the present disclosure. Accordingly, the present disclosure should not be interpreted restrictively by the experimental examples described below.

### Experimental Example 1: Manufacturing Photoelectric Device Modules and Photoelectric Conversion Module

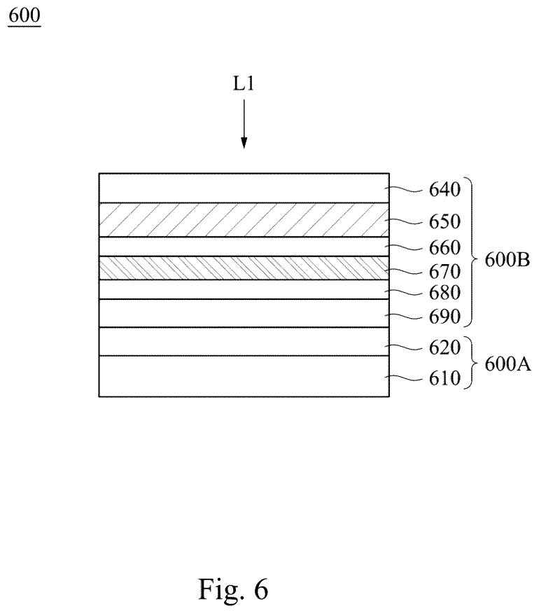

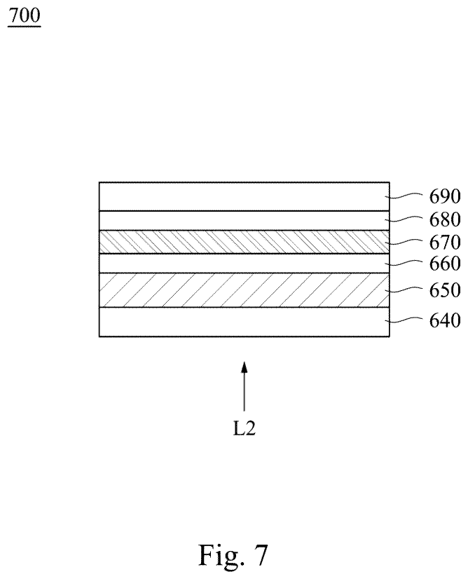

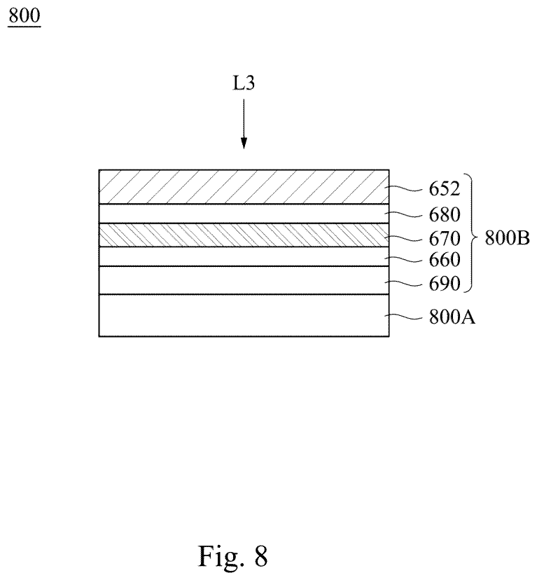

FIG. 6 is a schematic cross-sectional view of a photoelectric device module 600 of Example 1. FIG. 7 is a schematic cross-sectional view of a photoelectric conversion module 700 of Comparative Example 1. FIG. 8 is a schematic cross-sectional view of a photoelectric device module 800 of Comparative Example 2.

As shown in FIG. 6, the photoelectric device module 600 of Embodiment 1 includes a circuit module 600A and a photoelectric conversion module 600B that are connected to each other. The circuit module 600A includes a silicon substrate 610 and a silver electrode 620 disposed on the silicon substrate 610. The photoelectric conversion module 600B includes a glass substrate 640, an ITO electrode 650, a zinc oxide layer 660, a photoactive layer 670, a molybdenum trioxide layer 680, and a silver electrode 690. The photoelectric device module 600 can receive light L1 from above. The formation method of the photoelectric device module 600 includes the following operations. The glass substrate 640 covered with the ITO electrode 650 was pre-cleaned with a detergent and 2-propanol in an ultrasonic bath, and the glass substrate 640 was dried in an oven at 60° C. A zinc oxide solution was spin-coated on the ITO electrode 650 and heated at 120° C. for 10 minutes to form the zinc oxide layer 660 with a thickness of 40 nm. The P-type organic semiconductor with a formula (1) and the N-type organic semiconductor with a formula (2) with a molar ratio of 1:1.2 were dissolved in o-xylene to form a mixture, and the mixture was spin-coated on the zinc oxide layer 660 in a nitrogen atmosphere to form the photoactive which the is layer 670, in formula (1)

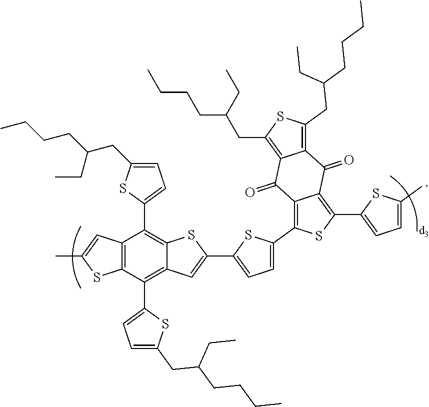

and the formula (2) is

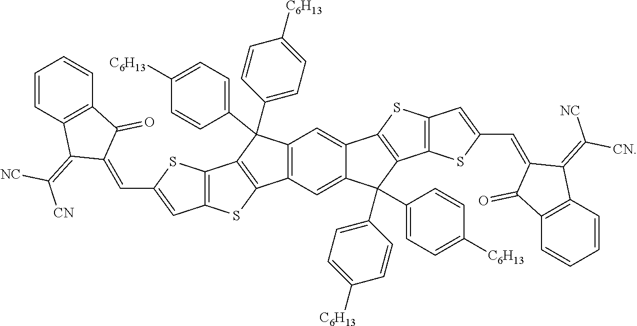

An annealing was performed at 120° C. for 5 minutes. Next, the molybdenum trioxide layer 680 with a thickness of 8 nm was deposited by thermal evaporation, and the silver electrode 690 with a thickness of 100 nm was deposited by thermal evaporation, thereby forming the photoelectric conversion module 600B. The silver electrode 690 of the photoelectric conversion module 600B and the silver electrode 620 of the circuit module 600A were adhered by silver paste. In addition, the photoelectric device module 600 was surrounded by an epoxy resin as a sealant (not shown) to adhere and encapsulate the circuit module 600A and the photoelectric conversion module 600B. It is worth noting that the photoelectric conversion module 600B is formed on the circuit module 600A by connecting rather than being directly deposited on the circuit module 600A, thereby prevent damage to the circuit module 600A or the photoelectric conversion module 600B during the manufacturing process.

As shown in FIG. 7, the photoelectric conversion module 700 of Comparative Example 1 includes a glass substrate 640, an ITO electrode 650, a zinc oxide layer 660, a photoactive layer 670, a molybdenum trioxide layer 680, and a silver electrode 690. The photoelectric device module 600 can receive light L2 from below. For the formation method of the photoelectric conversion module 700, please directly refer to the formation method of the photoelectric conversion module 600B in Embodiment 1.

As shown in FIG. 8, the photoelectric device module 800 of Comparative Example 2 includes a circuit module 800A and a photoelectric conversion module 800B. The circuit module 800A includes a silicon substrate with an opaque silver electrode. The photoelectric conversion module 800B includes a silver electrode 690, a zinc oxide layer 660, a photoactive layer 670, a molybdenum trioxide layer 680, and an IZO electrode 652. The photoelectric device module 800 can receive light L3 from above. The formation method of the photoelectric device module 800 includes the following operations. The silver electrode 690 with a thickness of 100 nm was deposited on the circuit module 800A by thermal evaporation. A zinc oxide solution was spin-coated on the silver electrode 690 and heated at 120° C. for 10 minutes to form the zinc oxide layer 660 with a thickness of 40 nm. The P-type organic semiconductor with the formula (1) and the N-type organic semiconductor with the formula (2) with a molar ratio of 1:1.2 were dissolved in o-xylene to form a mixture, and the mixture was spin-coated on the zinc oxide layer 660 in a nitrogen atmosphere to form the photoactive layer 670. An annealing was performed at 120° C. for 5 minutes. Next, the molybdenum trioxide layer 680 with a thickness of 8 nm was deposited by thermal evaporation. The IZO electrode 652 was deposited by sputtering to form the photoelectric device module 800. During sputtering, a layer with a thickness of 120 nm and a sheet resistance of 100 Ω sq⁻¹ was first deposited using a radio frequency power source. The IZO electrode 652 was deposited in an oxygen environment with a pressure of 10⁻³ torr and an operating power of 80 W. It is worth noting that the photoelectric conversion module 800B is formed by directly depositing the films of the photoelectric conversion module 800B on the circuit module 800A. Therefore, the process of manufacturing the photoelectric conversion module 800B may damage the materials in the photoelectric conversion module 800B. For example, the operation of forming the IZO electrode 652 may damage the molybdenum trioxide layer 680 and the photoactive layer 670 in the photoelectric conversion module.

### Experimental Example 2: Measuring Photoelectric Device Modules and Photoelectric Conversion Module

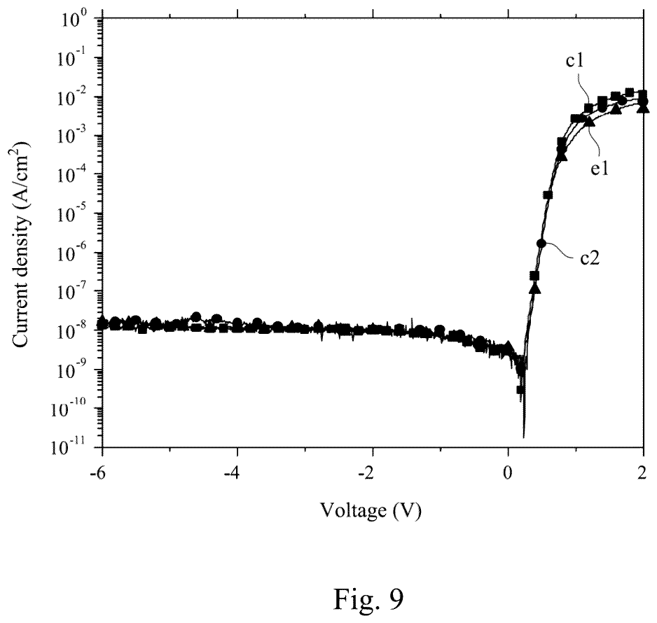

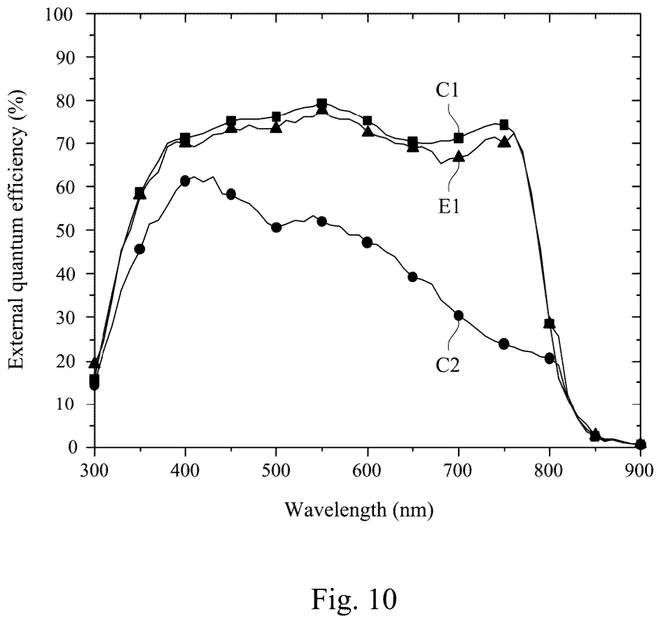

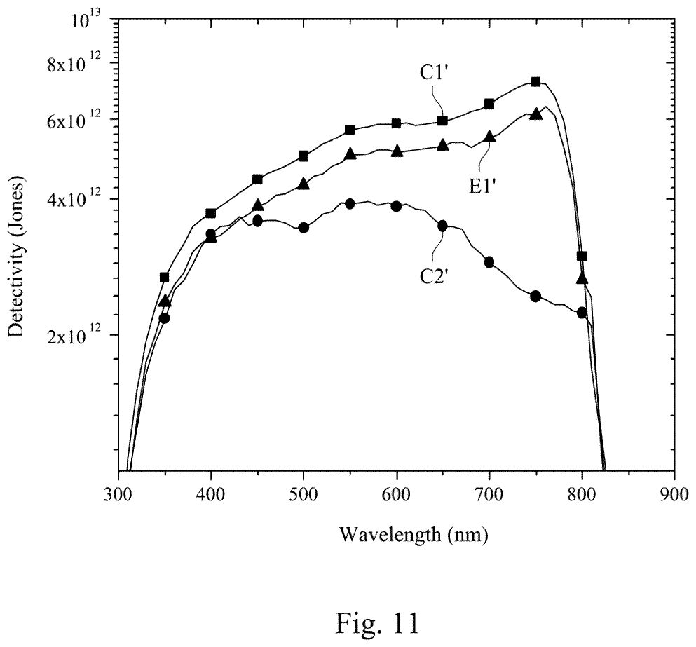

FIG. 9 is a current density-voltage diagram of the photoelectric device module 600 of Embodiment 1, the photoelectric conversion module 700 of Comparative Example 1, and the photoelectric device module 800 of Comparative Example 2. FIG. 10 is an external quantum efficiency-wavelength diagram of the photoelectric device module 600 of Example 1, the photoelectric conversion module 700 of Comparative Example 1, and the photoelectric device module 800 of Comparative Example 2. FIG. 11 is a detectivity-wavelength diagram of the photoelectric device module 600 of Embodiment 1, the photoelectric conversion module 700 of Comparative Example 1, and the photoelectric device module 800 of Comparative Example 2.

As shown in FIG. 7, the photoelectric conversion module 700 of Comparative Example 1 is measured by applying light L2. For the measurement results, please refer to the curve c1 of FIG. 9, the curve C1 of FIG. 10, and the curve C1′ of FIG. 11. The photoelectric conversion module 700 of Comparative Example 1 has the best performance in terms of the current density, external quantum efficiency (EQE), and detectivity. As shown in FIG. 6 and FIG. 7, the difference between the photoelectric device module 600 and the photoelectric conversion module 700 is that the photoelectric device module 600 further includes the circuit module 600A. The photoelectric device module 600 of Embodiment 1 is measured by applying light L1. For the measurement results, please refer to the curve e1 in FIG. 9, the curve E1 in FIG. 10, and the curve E1′in FIG. 11. It can be seen from FIGS. 9 to 11 that the current densities, EQE, and detectivity of the photoelectric device module 600 of Example 1 and the photoelectric conversion module 700 of Comparative Example 1 are similar, which represents that the connecting step in the process of manufacturing the photoelectric device module 600 has little impact on the properties of photoelectric device module 600.

Next, please refer to FIG. 8. The photoelectric conversion module 800B above the circuit module 800A is formed on the circuit module 800A by deposition. The photoelectric device module 800 of Comparative Example 2 is measured by applying light L3. For the measurement results, please refer to the curve c2 in FIG. 9, the curve C2 in FIG. 10, and the curve C2′ in FIG. 11. It can be seen from FIGS. 9 to 11 that the photoelectric device module 800 of Comparative Example 2 has the worst performance in terms of current density, EQE, and detectivity, which represents that the steps of depositing each layer of the photoelectric conversion module 800B on the circuit module 800A may cause the materials in the photoelectric conversion module 800B to be damaged, thereby affecting the properties of the photoelectric device module 800. It can be seen from the measurement results of Example 1 and Comparative Example 2 that the connecting step of Example 1 can enable the photoelectric device module 600 to maintain excellent photoelectric characteristics.

In summary, the present disclosure provides a photoelectric device module and a manufacturing method thereof. The photoelectric device module includes a circuit module and a photoelectric conversion module. The manufacturing method of the present disclosure can prevent the process of forming the photoelectric device module (such as the deposition process) from affecting the properties of the circuit module. Therefore, the photoelectric device module of the present disclosure can have excellent photoelectric characteristics, such as high current density, high EQE, and high detectivity.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A photoelectric device module, comprising:
a circuit module comprising a first electrode;
a photoelectric conversion module disposed on the circuit module, wherein the photoelectric conversion module comprises:
a second electrode electrically connected to the first electrode;
a photoactive layer disposed on the second electrode;
a light-transmitting electrode disposed on the photoactive layer; and
a light-transmitting substrate disposed on the light-transmitting electrode.

2. The photoelectric device module of claim 1, wherein the first electrode is in direct contact with the second electrode.

3. The photoelectric device module of claim 1, wherein the first electrode and the second electrode form an Ohmic junction.

4. The photoelectric device module of claim 1, wherein the light-transmitting substrate allows visible light, near-infrared light, or short-wave infrared light to pass through.

5. The photoelectric device module of claim 1, wherein a material of the light-transmitting substrate comprises polyimide, polyethylene terephthalate, polyethylene naphthalate, polycarbonate, silicon, or combinations thereof.

6. The photoelectric device module of claim 1, further comprising an optical functional layer, wherein the optical functional layer is disposed on the light-transmitting substrate or between the light-transmitting electrode and the light-transmitting substrate.

7. The photoelectric device module of claim 1, further comprising a conductive block, wherein the first electrode is electrically connected to the second electrode through the conductive block.

8. The photoelectric device module of claim 1, further comprising:
a first carrier transport layer disposed between the light-transmitting electrode and the photoactive layer; and
a second carrier transport layer disposed between the photoactive layer and the second electrode.

9. The photoelectric device module of claim 8, wherein the second electrode covers a lower surface and a side surface of the second carrier transport layer, a side surface of the photoactive layer, and a side surface of the first carrier transport layer.

10. The photoelectric device module of claim 1, wherein the circuit module further comprises a third electrode, and the third electrode is electrically connected to the light-transmitting electrode through a conductive block.

11. The photoelectric device module of claim 1, further comprising a sealant, wherein the sealant is disposed between an edge of the photoelectric conversion module and an edge of the circuit module, and the sealant, the photoelectric conversion module, and the circuit module surround a closed chamber.

12. The photoelectric device module of claim 1, wherein the photoactive layer comprises an organic semiconductor, an inorganic semiconductor, a quantum dot, perovskite, or combinations thereof.

13. A method of manufacturing a photoelectric device module, comprising:
receiving a circuit module, wherein the circuit module includes a first electrode;
forming a photoelectric conversion module, comprising:
forming a light-transmitting electrode on a light-transmitting substrate;
forming a photoactive layer on the light-transmitting electrode; and
forming a second electrode on the photoactive layer; and
connecting the circuit module and the photoelectric conversion module so that the second electrode is electrically connected to the first electrode.

14. The method of claim 13, wherein connecting the circuit module and the photoelectric conversion module is performed by bonding, adhering, or welding.

15. The method of claim 13, further comprising: before forming the light-transmitting electrode on the light-transmitting substrate, forming an optical functional layer to cover an upper surface of the light-transmitting substrate.

16. The method of claim 13, further comprising: before or after forming the light-transmitting electrode on the light-transmitting substrate, forming an optical functional layer to cover a lower surface of the light-transmitting substrate.

17. The method of claim 13, further comprising: disposing a sealant between an edge of the photoelectric conversion module and an edge of the circuit module to form a closed chamber surrounded by the sealant, the photoelectric conversion module, and the circuit module.

18. The method of claim 13, further comprising:
before forming the photoactive layer on the light-transmitting electrode, forming a first carrier transport layer on the light-transmitting electrode; and
before forming the second electrode on the photoactive layer, forming a second carrier transport layer on the photoactive layer.
